(19) United States
(12) Patent Application Publication
(10) Pub. No.: US 2012/0062190 A1
(43) Pub. Date: Mar. 15, 2012

(54) DC-DC CONVERTERS

(76) Inventors: Holger Haiplik, Swindon (GB); Seyed Hamed Sadati, Swindon (GB); Mark James McCloy-Stevens, Edinburgh (GB)

(21) Appl. No.: 13/229,101

(22) Filed: Sep. 9, 2011

Related U.S. Application Data
(60) Provisional application No. 61/381,517, filed on Sep. 10, 2010.

(51) Int. Cl. G05F 1/46; H03B 1/00

(52) U.S. Cl. 323/271; 327/109

(57) ABSTRACT

This application relates to switch mode DC-DC converter circuitry having a power switch operably connected between a supply node and an inductor node. The DC-DC converter has switch control circuitry for driving the power switch which is configured to controllably vary the rate of at least one of turn-on or turn-off of the first power switch. The rate may be based on the operational conditions of the converter, e.g. inductor current, one or more supply voltages and/or operating mode or activity level of a host device. By increasing the rate at which the switch turns-on or off switch transition power losses can be reduced. However a faster switching speed can lead to an increased voltage stress on the circuitry. Embodiments of the present invention varying the rate or turn-on and/or turn-off of the switch to reduce power losses but remain with the safe operating limits for the circuitry.

This application claims the benefit of U.S. Provisional Application Ser. No. 61/381,517, filed Sep. 10, 2010, the entire disclosure of which is herein incorporated by reference.

### BACKGROUND OF THE INVENTION

DC-DC switch-mode converters are increasingly being used in electronic equipment, e.g. as high-efficiency replacements for linear voltage regulators, especially for portable electronic equipment.

Many modern electronic devices may provide multiple different functions. For example a device may be useable as a mobile phone, a video player, an audio player and/or a gaming platform. These different functions may result in different load current demands. For instance if a multi-function device is being used as a gaming platform the processing load may be high which will typically lead to a relatively high load current demand whereas if the device is being used purely for audio playback the load current demand may be relatively low.

In order to ensure overall system efficiency it is therefore advantageous that the efficiency of a DC-DC switch-mode converter is optimised for its various possible load current demands, i.e. optimised for low as well as for high currents. This is especially the case for portable devices which may be battery powered. As feature sets of portable equipment tend to evolve faster than battery technology, the demands for higher DC-DC switch-mode converter efficiency over a wide load current range will generally increase.

For portable devices the supply voltage may be provided by a battery, for example a single cell Li-ion battery with a typical voltage of 3.7V or even a 3V single coin cell battery. At other times, however, a USB voltage supply of 5V and/or a different external voltage supply, e.g. a wall adapter, may be available. Ideally, the DC-DC converter should be most efficient at the typical supply voltage of the battery but without overstressing the DC-DC converter components when higher supply voltage is available.

In current day applications typical output voltages of DC-DC converters are 1.2V, to suit the supply voltages required for small-geometry digital circuitry. So step-down, or buck, DC-DC converters are used. However step-up, or boost, DC-DC converters are also often required for other applications as well as inverting converters, i.e. converters that produce an output voltage of opposite polarity to the input voltage.

With display screens of portable battery-powered devices becoming larger and larger and use cases becoming more and more display-focussed (gaming, web-browsing, etc.), generating the supply, typically 15-20V, for the backlight of the display can amount to the single biggest current consumption in a device. Boost converters are commonly employed to provide this supply. In order to minimise power consumption over different ambient light conditions the brightness of the backlight is usually adjusted in response to changing ambient light conditions; changing the brightness of the backlight is used additionally in order to enhance the viewing experience. To ensure optimum efficiency for different backlight brightnesses, the voltage of the backlight supply needs to be adjustable. Other applications may require a high-voltage supply to drive speakers, electromagnetic or piezoelectric, preferably with a variable output voltage to avoid wasting power at low or medium sound levels. There is thus also a need for a DC-DC boost converter with optimum efficiency over a range of output voltages and a range of output currents.

### SUMMARY OF THE INVENTION

The present invention therefore provides a DC-DC converter and methods of operation with improved efficiency.

Thus according to the present invention there is provided DC-DC converter circuitry comprising: a first supply node for connection to a first voltage supply line; a second supply node for connection to a second voltage supply line;

an inductor node for connection to an inductor; a first power switch operably connected between said first supply node and said inductor node; and
switch control circuitry configured to controllably vary the rate of at least one of turn-on or turn-off of the first power switch.

The switch control circuitry may be configured to vary said rate of at least one of turn-on or turn-off of the first power switch based on the operational conditions of the converter. The operational conditions may comprise the current flow out of the inductor node. The operational conditions may also comprise at least one supply voltage of the converter, e.g. one or more of an input supply voltage and an output supply voltage. The operational conditions may also comprise an activity level of the host system.

In another aspect of the invention there is provided a method of reducing power loss in a DC-DC converter having at least one power switch, the method comprising: varying the rate of at least one of turn-on and turn-off of at least one power switch. The rate may be varied based on the operational conditions of the converter.

### BRIEF DESCRIPTION OF THE DRAWINGS

The invention will now be described by way of example only with reference to the following drawings, of which:

FIG. 1 shows a conventional DC-DC buck converter;

FIG. 2 illustrates typical voltage and current waveforms for a buck converter during a two phase switching cycle in continuous conduction mode (CCM);

FIGS. 3a-3e illustrates voltage and current waveforms during the switch transitions from phase 201 to phase 202 shown in FIG. 2;

FIG. 4 illustrates the current flow during the switch transitions shown in FIG. 3;

FIG. 5 illustrates the losses, including switch transition losses, for the high-side switch during the transition shown in FIG. 3;

FIG. 6 shows an embodiment of a buck converter according to the present invention;

FIG. 7 illustrates one embodiment of a measuring block for determining current load and supply voltage;

FIG. 8 illustrates another embodiment of the measuring block;

FIG. 9 illustrates an embodiment of a translinear circuit for determining a value having defined proportionality to the inductor current and supply voltage;

FIG. 10 illustrates an embodiment of a programmable pre-driver;

FIG. 11 shows an alternative embodiment of a programmable drive strength pre-driver;

FIG. 12 illustrates the principles of another embodiment of a programmable drive strength pre-driver;

FIG. 13 shows an embodiment of a DC-DC boost converter according to the present invention;

FIG. 14 illustrates typical voltage and current waveforms for a boost converter during a two phase switching cycle in continuous conduction mode (CCM);

FIGS. 15a-15d illustrates voltage and current waveforms during the switch transitions from phase 1401 to phase 1402 shown in FIG. 14;

FIG. 16 illustrates the current flow during the switch transitions shown in FIG. 15;

FIG. 17 illustrates a flow chart of operation of switch control circuitry according to an embodiment of the invention;

FIG. 18 illustrates a flow chart of operation of switch control circuitry according to another embodiment of the invention;

FIG. 19 illustrates an embodiment of pre-driver having a variable slew rate;

FIG. 20 shows an embodiment of a DC-DC inverting converter according to the present invention;

FIG. 21 illustrates typical voltage and current waveforms for a inverting converter during a two phase switching cycle in continuous conduction mode (CCM); and

FIG. 22 illustrates a device having a DC-DC converter according to an embodiment of the present invention.

### DETAILED DESCRIPTION OF THE PREFERRED EMBODIMENTS

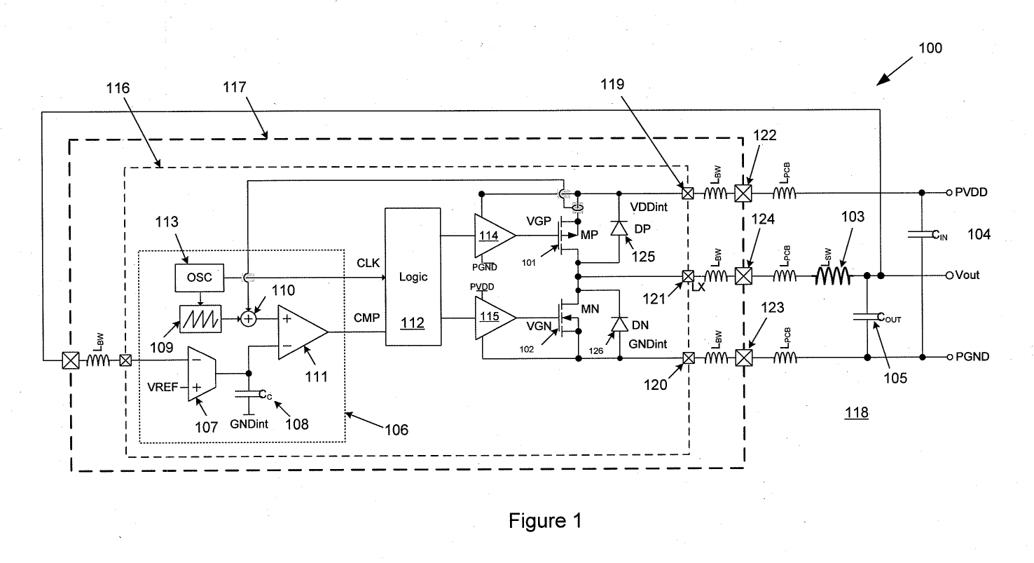

Referring to FIG. 1 an example of a conventional synchronous DC-DC buck converter circuit 100 is shown. A high-side power switch 101, in this case a PMOS switch, is connected between a supply node connected to high-side supply, PVDD, and a common inductor node, LX. A low-side power switch 102, in this case an NMOS switch, is connected between the common inductor node LX and a low-side node connected to a low-side or ground supply, PGND. An inductor 103 is connected between the inductor node LX and the output, Vout. An input decoupling capacitor 104 is connected between the input high-side supply and ground supply and an output smoothing capacitor 105 is connected between the output and ground supply. Single capacitors 104 and 105 are shown in FIG. 1 but it will be appreciated that either or both of these capacitances could be provided by multiple capacitors in combination.

Servo control circuitry 106 receives a feedback signal from the output voltage. This embodiment of a DC-DC converter is arranged to operate using current mode control, rather than e.g. voltage mode control, and so the servo control circuitry also receives an indication of inductor current, in this example by sensing PMOS source current. Various implementations of suitable control circuitry 106 are well known, but may include a differential transconductance amplifier 107 comparing the output voltage with a reference voltage, V_{REF}, a loop compensation capacitor 108, a ramp generator 109, a summing node 110, and a comparator 111 as illustrated. The output of this comparison is provided to logic 112 along with a clock signal from oscillator 113. The logic 112 drives pre-drivers 114 and 115 which respectively drive the high-side switch 101 and low-side switch 102.

In practice the DC-DC converter may be implemented as an integrated circuit within a package on a printed circuit board (PCB) for example. In the example embodiment shown in FIG. 1 the DC-DC converter is formed as an integrated circuit on a die 116 assembled inside a package 117 which in turn is attached to a PCB 118 which also in this case supports the decoupling and smoothing capacitors C_{IN} 104 and C_{OUT} 105. FIG. 1 illustrates that die bonding pads 119, 120, and 121 may be bonded to respective package terminals 122, 123 and 124 which in turn are soldered to tracks on a PCB, and that there will be internal parasitic inductances L_{BW} associated with the bond wires and the lead frame, and also external parasitic inductances L_{PCB} associated with the tracking on the PCB. In this example all the control circuitry is shown on the die 116 but it will be appreciated that various components described above could be located off chip, e.g. oscillator 113 or compensation capacitor 108.

As also shown in FIG. 1 the NMOS will typically have an associated diode 125 and the PMOS will have an associated diode 126. These diodes are shown as distinct diodes in FIG. 1 for the purposes of explanation but these diodes may be intrinsic body diodes associated with the transistors. The skilled person will appreciate that an NMOS transistor will typically have a parasitic drain bulk diode which may offer a parallel unidirectional conduction path when the NMOS switch is off and that similarly the PMOS may have an associated parasitic body diode. However in some embodiments there may be separate diodes associated with the transistors, for example for ESD protection or the like, which, if present, would also offer a parallel unidirectional conduction path when the relevant power switch is off.

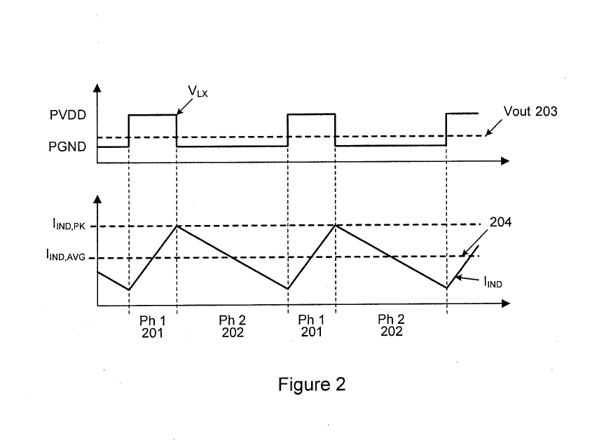

FIG. 2 shows typical voltage and current waveforms for a DC-DC converter in a typical step-down, i.e. buck converter, switching cycle in continuous conduction mode. The upper plot illustrates the voltage at node LX and the lower plot illustrates the inductor current. During one phase 201 of the switching cycle the high-side power switch 101 is closed, i.e. on, and the voltage at node LX is high and the inductor current increases. During another phase, 202, the high-side switch 101 is off and the low-side switch 102 is closed (on) and the voltage at node LX is low and the inductor current decreases.

The duty cycle of the two switching phases are controlled by the logic 112 based on the error signal to give the required output voltage. The average output voltage Vout and inductor current, i.e. load current, are indicated in FIG. 2 by dotted lines 203 and 204 respectively.

In general, the efficiency η of a DC-DC switch-mode converter, such as described above with reference to FIGS. 1 and 2, can be calculated as the power out P_{OUT} divided by the power in, P_{IN} where difference between the power in and power out is due to losses P_{LOSS}, i.e.:

$$η = \frac{{P}_{OUT}}{{P}_{IN}} = \frac{{P}_{OUT}}{{P}_{OUT} + {P}_{LOSS}} . \qquad Eqn . ( 1 )$$

Or alternatively, the inefficiency (1−η) is given by

$$1 - η - \frac{{P}_{LOSS}}{{P}_{IN}} - \frac{{P}_{LOSS}}{{P}_{OUT} + {P}_{LOSS}} . \qquad Eqn . ( 2 )$$

Embodiments of the present invention are aimed at improving the efficiency of a DC-DC switch-mode converter by reducing the power losses P_{LOSS}, in particular switch transition losses as will be described below.

Losses of a DC-DC switch-mode converter can generally be categorised into (a) quiescent current losses P_{Q}, (b) conduction losses P_{COND} and (c) switching losses P_{SW}.

Quiescent current losses P_{Q} are due to the quiescent current I_{DDQ} of a DC-DC switch-mode converter, for instance the quiescent current of any control circuitry such as 106 above. As quiescent current is usually small compared to the load current, and largely independent thereof, quiescent current losses are usually very small and only relevant at low load currents.

Conduction losses P_{COND} are a result of current flowing through resistive elements, for instance the on-resistances of MOS switches, of a DC-DC switch-mode converter. Conduction losses are a strong function of load current. They increase with increased load current and are the dominant losses at high load currents. Conduction losses can be reduced by reducing the resistance of the resistive elements of a DC-DC switch-mode converter.

Switching losses P_{SW} occur while opening and closing the power switches of a DC-DC switch-mode converter. For the case of MOS switches, they can be broadly categorised into (a) gate charge losses P_{SWG} and (b) switch transition losses P_{SWC}.

Gate charge losses P_{SWG} occur when repeatedly charging and discharging the gates of the MOS power switches, i.e. the high-side and the low-side switches, and depend on the gate capacitance of the power switches, the gate drive voltage and the switching frequency. These losses may be reduced by using the smaller channel length transistors now available with more advanced silicon technology. It is known that these losses can be optimised by adjusting gate drive voltage V_{G} for a given operating point in order to trade gate charge losses with conduction losses, or by reducing the number of parallel power switch elements used under lower loads.

However, there is a further type of power losses, switch transitions losses P_{SWC}, which have not previously been addressed. In essence switch transition losses occur due to the fact that, during a switch transition, i.e. transitions from an on state to an off state or vice versa, there may be a current flowing through a switch whilst there is a relatively significant voltage difference across the switch. This gives rise to instantaneous power dissipation much higher than the normal conduction losses of the switches, albeit for a small duty cycle.

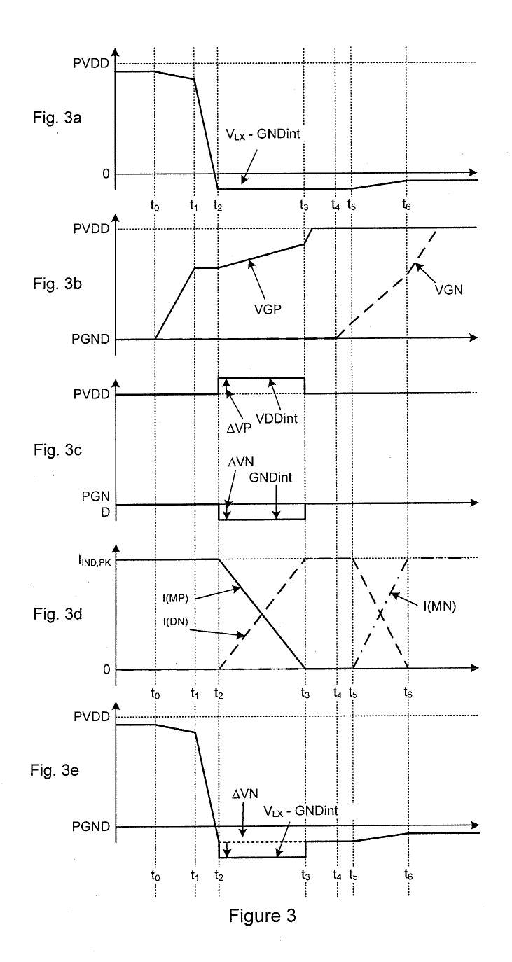

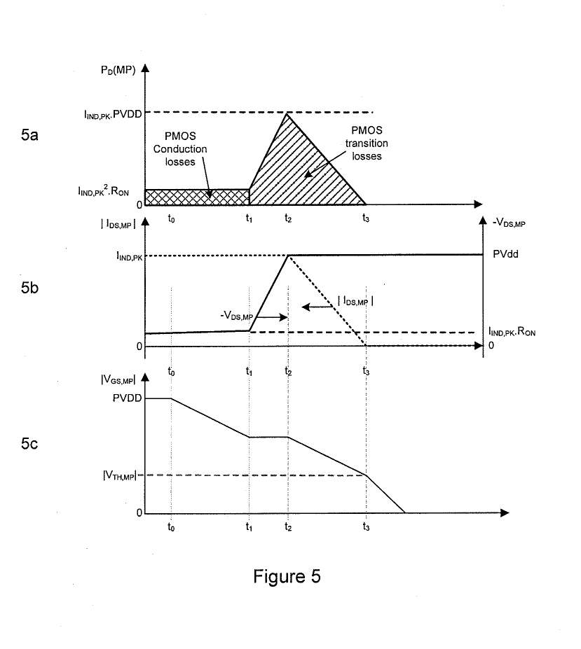

To explain switch transition losses the switching transitions from phase 201 of FIG. 2, where the high-side switch 101 (e.g. PMOS switch) is on and the low-side switch 102 (e.g. NMOS switch) is off, to phase 202 where the high-side switch is off and the low-side switch is on will be described with reference to FIGS. 3a-e and 4 with the power losses being illustrated in FIG. 5.

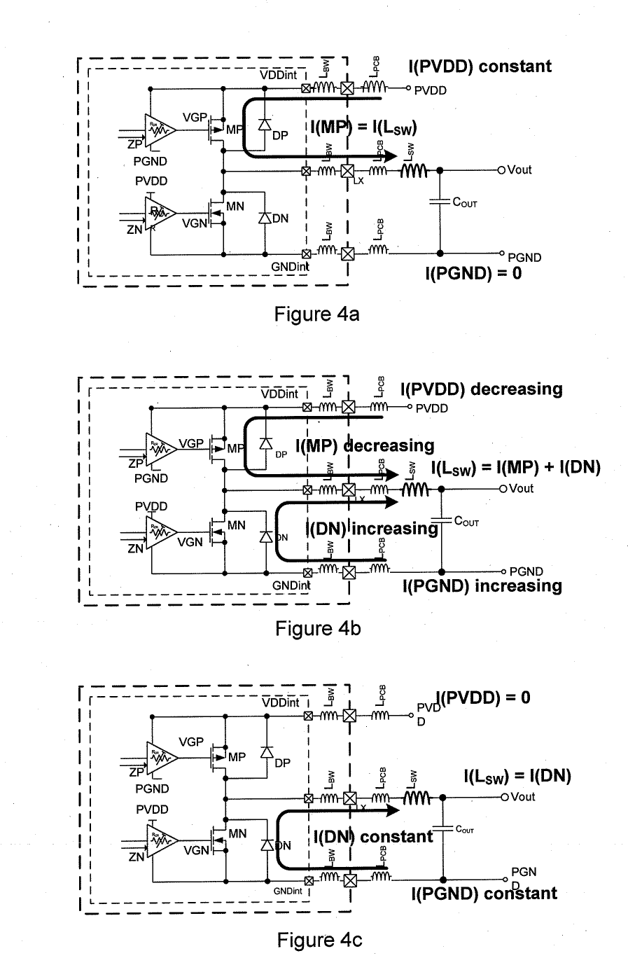

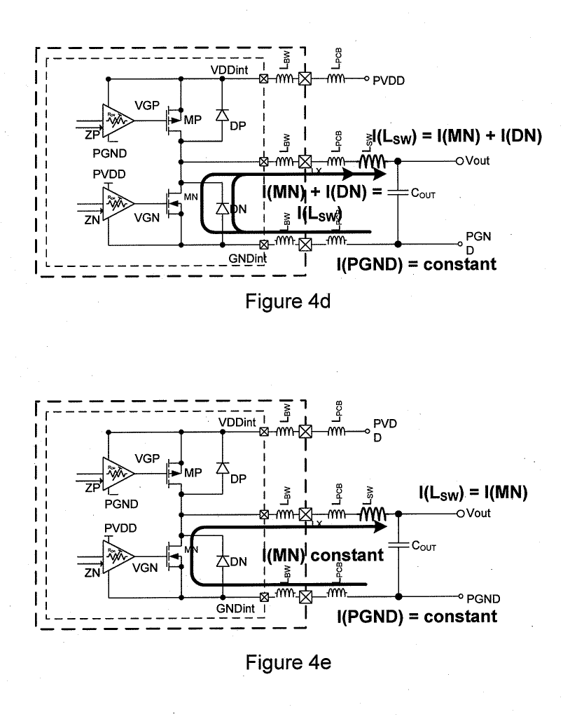

FIG. 3a illustrates the voltage V_{LX} at node LX with respect to the to the on-chip ground GNDint, i.e. the voltage at node 120, during the transition between phases. FIG. 3b shows the gate voltage, VGP, of the PMOS switch 101 and the gate voltage, VGN, of the NMOS switch 102. FIG. 3c illustrates the voltages developed at the internal, i.e. on chip, supply nodes of the DC-DC converter, e.g. the voltages developed at high-side supply node 119 and low-side supply node 120 of FIG. 1. FIG. 3d shows the current through the PMOS switch, I(MP), the current through the NMOS switch, I(MN), and also the current through the diode 126 associated with the NMOS switch, I(DN). FIG. 3e illustrates the voltage at inductor node LX with respect to the external ground, PGND. FIGS. 4a to 4e illustrate the current flow through the circuit at various parts of the transition between phases.

Before the transition begins the PMOS switch will be carrying all the inductor current, as illustrated in FIG. 4a. The inductor current will be ramping up, as described with reference to FIG. 2 above (phase 201), but over the timescales shown in FIGS. 3a-e the ramping will be too small to be noticeable. The voltage at node LX will be the supply voltage, PVDD, less a small voltage drop—mainly due to the on resistance of the PMOS switch. For a conventional PMOS the gate voltage VGP will be PGND and the PMOS switch will be hard on.

At a time t₀ the transition begins and the gate voltage VGP of the PMOS starts rising towards PVDD. At first, when the gate voltage VGP of the PMOS starts rising, the PMOS switch will still be able to carry the required current with only a slightly increasing on-resistance as the PMOS gate-source voltage reduces in magnitude, until, at time t₁, the gate voltage VGP has risen to a point where the PMOS gate-source voltage has reduced so much that the transistor cannot sustain the current anymore, at least with a small drain-source voltage Vds.

At this point the voltage at inductor node LX then drops rapidly. (At this point in the cycle, most of the current delivered from the pre-driver is used to charge the gate-drain capacitance of the PMOS rather than the gate-source capacitance, so the rate of change of VGP slows down.) Eventually, as the gate voltage VGP continues to rise, the PMOS switch is unable to supply the required current even with the full supply voltage between the PMOS drain and source.

In this example the NMOS switch is not turned on until the PMOS switch is fully turned off to avoid a shoot-through condition. So the NMOS switch cannot supply the remainder of the current demanded by the inductor. Thus the voltage at node LX drops below ground and starts to forward bias diode 126 associated with the NMOS. V_{LX} is then clamped at a diode voltage below the internal low-side supply voltage. At t₂ the current through the PMOS switch starts to decrease and ramps down to zero whilst the diode 126 takes an increasing share of the inductor current as illustrated in FIG. 4b. It will be noted that at this time, as the voltage at node LX is below zero, the inductor current will actually be decreasing as shown in phase 202 of FIG. 2. However again this change will be small on the timescales shown in FIGS. 3a-e.

As its applied gate voltage VGP increases further, the current through the PMOS switch continues to decrease, whilst the current through diode 126 increases until, at t₃, the PMOS current reaches zero and at this point all the inductor current is flowing through the diode 126, as illustrated in FIG. 4c.

It will therefore be clear that during the period between t₂ and t₃ the current through the PMOS switch from the supply line PVDD is decreasing rapidly. This will cause a noticeable kick or spike in voltage on the internal supply node VDDint 119 due the parasitic inductances associated with the high voltage supply, L_{VDD}, where in the example of FIG. 1 L_{VDD}=L_{BW}+L_{PCB} for the supply line. This voltage change, ΔVP, will be given by:

$$Δ VP = {L}_{VDD} \times \frac{d I ( MP )}{d t} \qquad Eqn . ( 3 )$$

where I(MP) is the current through the PMOS switch.

The polarity of this voltage kick ΔVP is to increase the voltage at internal node 119 relative to the supply voltage, PVDD.

Similarly, the equally quick rise in current though the parasitic inductances L_{GND} (=L_{BW}+L_{PCB}) on the low-side supply line will give rise to a negative voltage kick, ΔVN of magnitude at the internal low-side supply node 120:

$$Δ VN = {L}_{GND} \times \frac{d I ( DN )}{d t} = {L}_{GND} \times \frac{d I ( MP )}{d t} . \qquad Eqn . ( 4 )$$

Once the current through the PMOS switch reaches zero at t₃ clearly the current through the high-side supply will also be zero and constant (as illustrated in FIG. 4c). The current through the low-side supply line will now also be constant (on the timescales of FIGS. 3a-e). Thus both voltage differences will recover to zero, i.e. the induced voltage kicks ΔVP and ΔVN will cease.

Referring back to FIG. 3b, at a time t₄ the turn-on of the NMOS switch 102 begins. The gate voltage of the NMOS is increased and, once a threshold is reached at time t₅, the NMOS switch starts conducting, as illustrated in FIG. 4d. As the gate drive of the NMOS ramps up it takes an increasing amount of the current from the diode 126 until, at time t₆, the NMOS switch is providing all the required current and no more current is flowing through the diode 126, as illustrated in FIG. 4e. The NMOS switch 102 is now fully on. During the NMOS switch turn-on the total current flowing through the low-side supply line is essentially constant (and the current through the high-side is zero) and hence there is no voltage kick on the internal nodes during this transition.

It should be noted that FIGS. 3b and 3d show the NMOS switch only beginning to turn on after the PMOS switch current has dropped to zero. The skilled person will appreciate that the NMOS switch may be turned on at any time after the voltage at node LX (shown in FIG. 3a) has dropped below ground in order to reduce the amount of time where conduction is via diode 126. However the principles will be the same—the diode 126 will take a share of the current until the NMOS switch has turned on to a sufficient extent to provide all the required current, and the total ground current will still ramp at the same rate as the decrease in PMOS switch current, giving a low-side voltage kick until the PMOS switch current becomes zero.

As stated above, FIG. 3a shows the voltage at inductor node LX with respect to internal ground GNDint, in particular showing that VLX goes a diode voltage below GNDint between t2 and t4. However, as illustrated in FIG. 3c, the voltage at GNDint kicks down by a voltage ΔVN between t2 and t3. The voltage at LX with respect to the external ground is thus as shown in FIG. 3e.

It will be appreciated that in practice the voltage kicks on the internal supply nodes, i.e. bond pads or terminals, 119 and 120 may alter the detailed shape of VGP and VGN, but the overall behaviour will still be similar to that shown. Other second order effects are also neglected in the discussion above. For instance the voltage at LX may well ring, due to parasitic capacitances resonating with the inductances, especially when the sudden voltage ramp between t1 and t2 terminates. An RC snubber network may be attached to this node to reduce any such ringing, as is known.

The switch transition losses during turn-off of the PMOS switch can therefore be identified from the foregoing with reference to FIG. 5. The lower plot (FIG. 5c) shows the (negative) gate-source voltage, V_{GS}, of the PMOS and the middle plot (FIG. 5b) shows the (negative) drain-source current, I_{DS}, and voltage, V_{DS}, of the PMOS during the transition shown in FIG. 3. The upper plot (FIG. 5a) illustrates the switch conduction losses associated with the switch being on and also switch transition losses (in this case the PMOS switch transition losses) P_{SWC}.

Initially, when the PMOS switch is fully on, the voltage at node LX is near the supply voltage and the drain source voltage is small. Power losses at this point in the cycle are the normal conduction losses:

I_{DS}·V_{DS}=I_{DS}²·R_{ON}=I_{IND}²·R_{ON} Eqn. (5)

where R_{ON} is the on-resistance of the PMOS switch and I_{IND} is the inductor current, which, for the PMOS switch just before turn-off, will be the peak inductor current I_{IND,PK} shown in FIG. 2.

At t₀, the pre-driver 114 starts increasing the PMOS gate voltage VGP. The magnitude of the drain-source voltage across the PMOS switch, |V_{DS}|, may increase slightly due to the fact that the on resistance of the PMOS switch will increase as a result of the decreased PMOS gate-source voltage |V_{GS}|, but the resulting extra loss is minor. However once the voltage at node LX starts ramping down at time t₁, the magnitude of the drain-source voltage across the PMOS switch, |V_{DS}|, rapidly increases, along with the associated power loss |I_{IND,PK}|·|V_{DS}|. Then, at time t₂, when |V_{DS}| becomes clamped at about the supply voltage PVDD (neglecting the diode voltage and voltage kick for simplicity), resulting in a peak power dissipation of about I_{IND,PK}·PVDD. While |V_{DS}| is clamped at this high voltage, the current |I_{DS}| of the PMOS switch ramps down from I_{IND,PK} to zero.

The losses occurring (in the PMOS switch) between the time t₁ and the time t₃ in the transition are the switch transition losses. Although these I_{DS}·V_{DS} power losses between t₁ and t₃ are still due to power dissipated in the PMOS switch, it will be appreciated that their instantaneous power level is much higher and duty cycle much lower than the conduction losses when the PMOS switch is fully on.

The energy lost during this switch transition is given by the area under to the trace of FIG. 5a between t₁ and t₃ and this loss occurs at a rate equal to the switching frequency f_{SW} so the average switch transition power loss contribution can be calculated as approximately:

P_{SWC}=½×V_{PVDD}×i_{IND}×(t_{R}+t_{F})×f_{SW}. Eqn. (6)

where V_{PVDD} is the value of the voltage at PVDD, i_{IND} is the inductor current (i.e. I_{IND,PK}) at the time the switching occurs, t_{R}=t₂−t₁ and t_{F}=t₂−t₂ are the rise and fall times.

These switch transition losses could therefore be reduced by decreasing the rise/fall times mentioned above. This can be achieved by opening, i.e. turning off, the PMOS switch 101 quicker.

However, opening the PMOS switch more quickly will lead to a greater rate of current change, di/dt. As described above the rapid change in current through the high and low supply lines leads to a voltage kick on the internal supply nodes due to parasitic inductances in the supply lines. A higher rate of current change will induce a larger voltage across these parasitic inductive elements. If this induced voltage is too high, the resultant voltage (supply voltage plus ΔVP and ΔVN and possibly the diode voltage) across the switches 101 and/or 102 may exceed a breakdown voltage of any one of the switches, which may lead to damage/failure of the switches. Whilst efforts are made to minimise such parasitic inductances in circuit design most practical converters will suffer from some such parasitic inductances.

Conventional DC-DC converters are designed with switch transition times slow enough to avoid damage under the worst envisaged system operating conditions of supply voltage and current. Thus in different system operating conditions, the transition times are unnecessarily slow, and switch transition losses are higher than necessary.

Table 1 below shows some illustrative power losses for a typical DC-DC buck converter operating at two different input supply voltage levels, 5.5V or 2.5V. In both cases the output voltage is taken to be 1.3V and an inductor current of 1.2 A is assumed.

The losses shown in Table 1 are expressed as percentages calculated individually by Pi/(Pi+Pout) (similar to Equation 2 above) where Pi is each factor calculated separately. These losses include conduction losses, quiescent current losses and switching losses as described above. The conduction losses are illustrated individually for the NMOS switch, PMOS switch and the diode (diode recirculation losses). Conduction losses are also illustrated for the inductor (Inductor ESR or equivalent series resistance losses) and the bond wire resistances. The switching losses are broken down into the gate charge losses discussed above and PMOS switch transition and NMOS switch transition losses. The switching losses are calculated for a full switching cycle of the converter. The PMOS transition losses can be seen to be the largest single factor for Vin=5.5V and the third largest for Vin=2.5V.

TABLE 1

Pi/(Pi + Pout) (%)

| | Vin = 5.5 V, Vout = | Vin = 2.5 V, Vout = |
|---|---|---|
| | 1.3 V, IL = 1.2 A | 1.3 V, IL = 1.2 A |
| NMOS conduction | 8 | 5.6 |
| PMOS conduction | 3.3 | 11.8 |
| Diode recirculation | 1.2 | 5.8 |
| PMOS transition | 9.8 | 6.5 |
| NMOS transition | 0.8 | 0.9 |
| Gate charge | 1.2 | 0.3 |
| Inductor ESR | 6.9 | 6.9 |
| Bond wires | 1.6 | 1.6 |
| Quiescent | 0.1 | 0.05 |

In an embodiment of the present invention these switch transition losses are reduced in DC-DC switch-mode converters by using switch control circuitry configured to controllably vary the rate of at least one of turn-on or turn-off of a first power switch of the converter. By the rate of turn-on or turn-off is meant the rate at which the switch properties (e.g. gate voltage or conductivity or resistivity of the channel) vary during the turn-on or turn-off transition. Consequently the rate of turn-on or turn-off of the switch determines how quickly the current through the switch ramps up (for turn-on) or ramps down (for turn-off) and hence the magnitude of any induced voltage kick. In general therefore controllably varying the rate of turn-on or turn-off of a switch comprises controlling the rate of current ramping, i.e. di/dt, through the switch. The rate of turn-on or turn-on can also be seen as the switching speed of the switch transitions.

The aim is to open or close a power switch as fast as possible under the prevailing operating conditions of the DC-DC converter to minimise switch transition power losses without damaging the power switches or any other circuitry, either directly or indirectly associated with the DC-DC converter, through over-voltage stress.

The first power switch is operably connected between a first supply node (i.e. a node connected to an input or an output supply line of the converter) and the inductor node (i.e. a node that is operably connected to one side of an inductor in use). The first power switch may thus be connected directly to said nodes or via other circuit elements such as current sensors or the like. In general however the first switch is arranged to provide, when it is on, a current path between the first node and the inductor node.

Depending on the converter arrangement, as will be described in more detail later, the first supply node may be an input supply node (for receiving an input voltage, e.g. PVDD or for connection to ground PGND) or the first supply node may be an output supply node for providing an output voltage. As mentioned, in use the inductor node will be operably connected to an inductor. The other end of the inductor may, depending on the converter arrangement, provide an output supply or it may be connected to an input supply voltage (or in some buck-boost converters both ends of the inductor may be connected to the circuitry of the converter). For converters with a second power switch connected between a second supply node and the inductor node the rate of turn-on and/or turn-off of the second power switch may also be controlled.

In embodiments of the present invention the rate of turn-on or turn-off of at least the first power switch is controlled based on the operational conditions of the converter. The operational conditions may include at least one of: the current flow through the inductor node; an indication of the actual or expected current flow through the inductor node; at least one supply voltage of the converter; an operational mode of the host device/system and the activity level of a host system.

The rate of turn-on or turn-off may be based on the current flow out of the inductor node (i.e. towards the inductor or away from the inductor) as this current (which is in effect the inductor current) represents the current carried through the supply lines.

For switch transitions that involve a change in current on the supply lines of the DC-DC converter, such as the PMOS switch turn-off described above, the amount of current change will clearly depend on the magnitude of the inductor current. The rate of switching (i.e. rate of turn-on or turn-off of the switch) determines how quickly said current change occurs. For a relatively lower inductor current the rate of switching can be greater (quicker), i.e. the current can change between the value of the inductor current and zero in a shorter time, than for a relatively higher inductor current to provide the same rate of current change, di/dt, and hence the same magnitude of any induced voltage kick.

As the skilled person will appreciate the current flow through the inductor node can be determined by determining the current flow through another element of the circuit, for example through a sense resistor or through the first power switch or another switch element and the converter may have current sense circuitry as will be described in more detail later. The current flow through the inductor node may also be determined from other properties of the converter or the host system, for example the activity level or operating mode of the host system. The rate of turn-on or turn-off may be controlled based an indication of the magnitude of the inductor current, which may be a relatively coarse indication, such as high or low current, e.g. above or below a threshold. The rate of turn-on or turn-off may also be controlled based an indication of the polarity of the inductor current, i.e. whether the current is flowing from the inductor node towards the inductor or in the opposite direction.

Additionally or alternatively the rate of turn-on or turn-off of a power switch may be controllably varied based on at least one supply voltage. For a DC-DC buck converter the supply voltage of interest is the input supply voltage. As described earlier, at various points in the cycle the voltage at the inductor node LX may be near PVDD or near PGND and hence it will be clear that the input supply voltage is applied across the power switch in operation. Thus the maximum static voltage across the power switch, i.e. the maximum voltage in the absence of any induced voltage kick, depends upon the input supply voltage and hence the magnitude of the superimposed voltage kick that can be tolerated also depends on the input supply voltage. For a boost converter, as will be discussed in more detail below, the output supply voltage is the supply voltage of interest as the output voltage is applied across the switch in use and is larger than the input supply voltage. In general the voltage difference between the supply voltages (whether input or outputs voltages) at the supply nodes of the converter is the supply voltage of interest. For inverting converters where the output voltage developed on one of the supply nodes may be of opposite polarity to the input voltage on the other supply node of the converter both the input and the output voltages are of interest and the maximum static voltage difference is equal to |PVDD|+|Vout|.

The switch control circuitry may be any suitable circuitry that can drive the power switch and which can control the rate of turn-on and/or turn-off of the switch. In general the switch control circuitry may have a drive output for driving the power switch and may vary the electrical properties of the drive output so as to control the switching rate. The rate of turn-on, or turn-off, of the power switches can be varied by varying the drive strength of pre-drivers driving the power switches. As will be understood by one skilled in the art, varying the drive strength of the pre-driver will vary how quickly the power switch turns on or off, and thus vary the rate of current change within the switch. The drive strength may be adaptively modified in order to make sure the supply voltage plus the induced voltages across inductive elements is always lower than any of the breakdown voltages of the switches, but close to the upper limit of the safe operating area (SOA). Thus the switch control circuitry may comprise at least one pre-driver having a variable drive strength and pre-driver control circuitry for controlling the driver strength of the at least one variable strength pre-driver.

The higher the drive strength of the pre-driver, the faster the relevant switch transition. For example, referring to the PMOS switch turn-off described above with reference to FIGS. 3 to 5, the pre-driver for the PMOS switch (pre-driver 114 in FIG. 1) discharges the output stage capacitances in order to turn the PMOS switch off. Simplistically in the period between t₁ and t₂ it is the gate-drain capacitance of the PMOS switch and a higher drive strength (which as will be described can be seen as a lower output resistance) results in a faster discharge (to a first order the slope of the voltage change at node LX is determined by the gate-drain capacitance of the PMOS switch and the output resistance of the pre-driver). In the period between t₂ and t₃ it is the gate capacitance of the PMOS switch which is discharged (in this case a lower output resistance, i.e. higher driver strength, for the pre-driver will result in the gate-source voltage decreasing faster and consequently the gate capacitance discharging quicker). As mentioned above, in both of these periods a higher drive strength of the pre-driver will discharge the capacitances more quickly and doubling the drive strength will approximately halve the duration of each of these periods.

It will of course be appreciated that the induced voltage kick only occurs in the period between t₂ and t₃ when there is a change in current flowing in the supply lines of the converter. Therefore the drive strength during the period t₁ and t₂ could be set as high as possible to ensure that this part of the switch transition occurs as fast as possible, with a variable drive strength (based on inductor current and/or the input supply voltage) being applied to the part of the transition where the PMOS switch current falls. It is simpler to set an appropriate drive strength for the entire switch transition, but especially in future with smaller and faster technologies, it may be more practical to implement the fast detection and response circuitry required to vary the drive strength appropriately during the switch transition and it should be understood that the principles of the present invention apply to varying the drive strength of a pre-driver even for only part of the switch transition based on the operational conditions of the converter.

The skilled person will appreciate that, for most practical pre-drivers having relatively high output resistances, the drive strength of the pre-driver is related to the equivalent output resistance of the pre-driver circuitry. The lower the equivalent output resistance of the pre-driver the higher the drive strength. The drive strength can therefore be seen as effectively the reciprocal of the output resistance. The drive strength can equally be seen as the output current drive in a Norton equivalent circuit for the pre-driver circuitry (rather than the output resistance in a Thevenin equivalent circuit). Were however a pre-driver to be implemented using a low impedance voltage source with a defined voltage slew rate independent of load, the switching periods would be defined by the slew rate and for such a pre-driver the term drive strength should be taken to mean the relevant slew rate.

The rate of switching may be adjusted for each switching transition for each switch, in other words the rate of both turn-on and turn-off for each of the switches may be varied based on the prevailing conditions. The rate of switching may be adjusted separately for turn-on as for turn-off and/or the rate may be varied differently for each switch. However in some embodiments the rate of only some of the switch transitions may be varied. For instance the rate of turn-off of a power switch may be varied based on the supply voltage and/or inductor node current but the rate of turn-on of the same switch may not be so varied. For DC-DC switch-mode converters with a plurality of power switches a switch transition rate may be varied for one of the power switches but not the other.

For example, the discussion above has focussed on the switch transition losses occurring during turn-off of the high-side switch, i.e. PMOS switch 101, in a step-down (buck) switching cycle.

For a step-down converter such as described, subsequent turn on of the NMOS switch will typically give rise to much less significant switch transition losses as the maximum voltage across the NMOS switch during the switch transition will typically be, at most, a diode voltage. Referring back to FIG. 3a it can be seen that at the start of the NMOS switch turn-on, t₄, there is a diode voltage across the NMOS switch which reduces to the voltage drop due to the on-resistance of the NMOS switch by the time t₆ that the NMOS switch is fully on. Further, as described above, if the NMOS switch is turned on only after the PMOS switch current has dropped to zero there will generally be no significant change in current in the supply lines during the switch transition and so there is no voltage kick to consider. Even if the NMOS switch were to be turned on slightly earlier (but after LX has fallen below ground to avoid shoot-through current) to reduce Id. Vd losses, as described above, the transfer of current from the diode to NMOS switch does not (to first order) affect the total ground current ramp rate, which is still defined by the PMOS switch current ramp rate. Therefore, in such a converter, the NMOS switch turn-on rate may be set to be as fast as possible given the available components (taking into account issues such as ringing and voltage overshoot) and not varied in use based on changes to inductor current or supply voltage.

The other transitions in the cycle, i.e. from phase 202 to phase 201 of FIG. 2, where the NMOS switch turns-off and the PMOS switch turns-on may be analysed in a similar way to that above.

For turn-off of the NMOS switch the voltage change across the NMOS switch is typically at most a diode voltage. If the inductor current is always positive (or zero), i.e. any inductor current is always towards the load (and thus current through the inductor node is always towards the inductor) and doesn't reverse, there will also be no change in current via the supply lines (as the NMOS switch turns off, the diode 126 will supply any necessary current) and hence no voltage kick to consider. Thus, if the inductor current never reverses the NMOS switch turn-off rate may also be fixed.

When the PMOS switch then turns on, the PMOS switch current will increase rapidly and take an increasing share of the inductor current from diode 126. At this time the voltage at node LX will generally be clamped at a diode voltage below ground and so there will be a voltage difference of about PVDD across the PMOS switch. Therefore relatively significant switch transition losses may be encountered. This rapid draw of current via the high-side supply line and rapid drop of current via the low-side supply line induces voltages in the parasitic inductances as described above. However in this instance the polarity of the voltage kick is to actually bring the voltages at the internal supply nodes 119 and 120 closer together.

Therefore for the PMOS switch turn-on in a step-down switching scheme as described, increasing the switching speed (i.e. rate of turn-on) does not lead to an increased voltage stress on the components due to a voltage kick at the internal nodes. Thus in some embodiments the rate of turn-on of PMOS switch may also be fixed. Therefore in an embodiment of a DC-DC buck converter according to the present invention only the rate of turn-off of the high-side switch is varied based on the operational conditions, e.g. inductor node current and/or input supply voltage.

There may however be a degree of ringing of the voltages at internal supply nodes 119 and 120 due to a switch transition. The voltages at internal supply nodes may exhibit some ringing when the voltage kick due to the rapid change in current subsides. The same effect can occur following the rapid change in current due to PMOS switch turn-on and in this case the ringing may actually result in a maximum voltage across the components that exceeds the supply voltage. The extent of the ringing may be related to the rate of current change and hence the switching speed. The ringing may be damped by the use of appropriate circuit components, for instance an RC damping (snubber) circuit. However in some embodiments it may be desirable to adjust the rate of turn-on of the PMOS based on the supply voltage and/or inductor current so that any voltage maximum caused by ringing does not exceed the safe operating area of the components. Because of the complexity of the factors that influence such ringing any adjustment is likely to be an empirical adjustment based on simulation or testing and appropriate values of rate of switching transition may be stored in a look-up table or similar.

The above consideration of the NMOS switch turn-off and the PMOS switch turn-on assumes that the inductor current is positive, i.e. current is flowing towards the load, or zero. For some applications current reversal, i.e. current flowing away from the load, may generally be prevented to avoid inefficiency. Thus the DC-DC converter may, for example, operate in discontinuous conduction mode rather than allow current reversal and in such a case the analysis above will generally be true. However in some embodiments the inductor current may reverse during the NMOS switch conduction period. This may be necessary for supply for some components, such as certain types of memory, or may occur during load transient conditions.

For example in order to optimise load transient performance of a constant frequency DC-DC converter it should be operated in continuous conduction mode (CCM). Assume that the load current of a constant frequency DC-DC converter operating in CCM is high and suddenly decreases to zero. Due to the limited bandwidth of the control circuitry, the DC-DC converter will continue to provide the previous load current to the output which is stored in the output capacitor, resulting in an overshoot of the output voltage. In order to bring the output voltage back into regulation, the control circuitry (once it starts to react to the load current change) will reduce the current that the DC-DC converter provides. Eventually the output current will reach zero, at which point the output voltage stops increasing. At this point the output current of the DC-DC converter will become negative, and hence the DC-DC converter will discharge its output capacitor via the NMOS switch. During this time, as described below, the switch transition loss of the NMOS switch will be relevant when turning the NMOS switch off, and the PMOS switch will be less relevant.

Also, in some applications a DC-DC converter may be used to supply a circuit that can sink or source current. For example some DDR memories require a termination voltage Vtt from a supply that can source or sink current and a DC-DC converter used in such applications may be used with significant negative current flow. Again the NMOS switch transition losses when turning the NMOS switch off may be more important than those from PMOS switch under the conditions of negative inductor current flow, and the respective pre-driver strength will be adapted according to the detection or prediction of such conditions.

In any case, if the inductor current has reversed at the time that the NMOS switch turns off then, as the NMOS switch turns off the current flowing from the load will increasingly flow through diode 125 associated with the PMOS switch. In this situation as the NMOS switch turns off there will be a rapid change in current flow at both the low-side supply and high-side supply. At the high-side supply there will be a rapidly increasing reverse current and hence there will be a voltage kick to increase the voltage at supply node 119. Similarly at the low-side supply there will be a rapidly decreasing reversed current and thus there will be a voltage kick to decrease the voltage at low-side supply node 120. These voltage kicks will therefore increase the voltage difference across the power switches 101 and 102 and add to the voltage stress on the components. Thus in some embodiments the rate of the NMOS switch turn-off may be varied taking account of the supply voltage and/or the inductor current magnitude and polarity. For example the NMOS switch turn-off and PMOS switch turn-on may be configured to occur at high speed, e.g. with a strong pre-drive, in usual operation where a positive polarity of inductor current can be guaranteed, but to occur with a reduced speed (or weaker pre-drive) when a substantial negative inductor current is anticipated or detected.

It will be appreciated that in conditions of current reversal the turn-off of the PMOS switch will actually result in a negative voltage kick, i.e. the kick will bring the voltages at the internal supply nodes closer together. Thus if current reversal is detected the PMOS turn-off can be set to be as fast as possible.

It will of course be appreciated that the discussion above has assumed that the high-side supply is a positive voltage supply and that the low-side supply is ground. In some embodiments the high-side supply may be a high negative voltage and the polarities of various voltage and current waveforms may be different to those shown above, and some changes in circuit components may be necessary as will be obvious to one skilled in the field, for example the high-side switch may be an NMOS switch. The general principles of changing the rate of a switch transition to reduce switch transition losses whilst remaining within safe operating limits for the switches and other components apply equally to such converters and such embodiments are clearly within the ambit of the present invention.

The switch transitions for which there is a trade off between increased efficiency with faster switching speed (through reduced switch transition losses) but increased induced voltage kicks leading to increased voltage stress may vary for different designs of converter but the general principles are the same. The skilled person will readily be able to determine, for a particular converter design, those switch transition where a variation in the rate of transition based on the supply voltage and/or inductor current would be beneficial.

As mentioned the rate of a switch transition (i.e. turn-on or turn-off), for a buck converter, may be varied based on an indication of the supply voltage (which when the low-side supply is ground is equal to the high-side supply voltage). As described above, with reference to FIG. 3c, the maximum voltage difference between internal supply nodes 119 and 120 is equal to the supply voltage plus any voltage kicks induced in the parasitic inductances, i.e. equal to PVDD+ΔVP+ΔVN, although as the node LX is clamped at a diode voltage below the internal ground node there is actually a maximum voltage difference across the PMOS switch equal to PVDD+ΔVP+ΔVN+the diode voltage. If the circuit components have a maximum safe operating voltage then clearly the larger the value of the supply voltage PVDD the smaller the value of voltage kick (that increases the voltage across the components) that can be tolerated. For a portable device the supply voltage may vary in use. If a device receives a 5.0V USB supply the maximum voltage kick that can be allowed will be lower than if the supply is a battery voltage at 3.7V.

Additionally or alternatively the rate of switch transition may be varied based on an indication of inductor current. The voltage kick is based on the rate of change of inductor current, which clearly depends on the time taken for the relevant switch to turn on or off and the amount by which the current rises or falls. Consider the PMOS switch turn-off example discussed above. For a given duration for the PMOS switch current to fall to zero, i.e. a switch turn-off time, a doubling of the inductor current will lead to a doubling of the magnitude of the voltage kick.

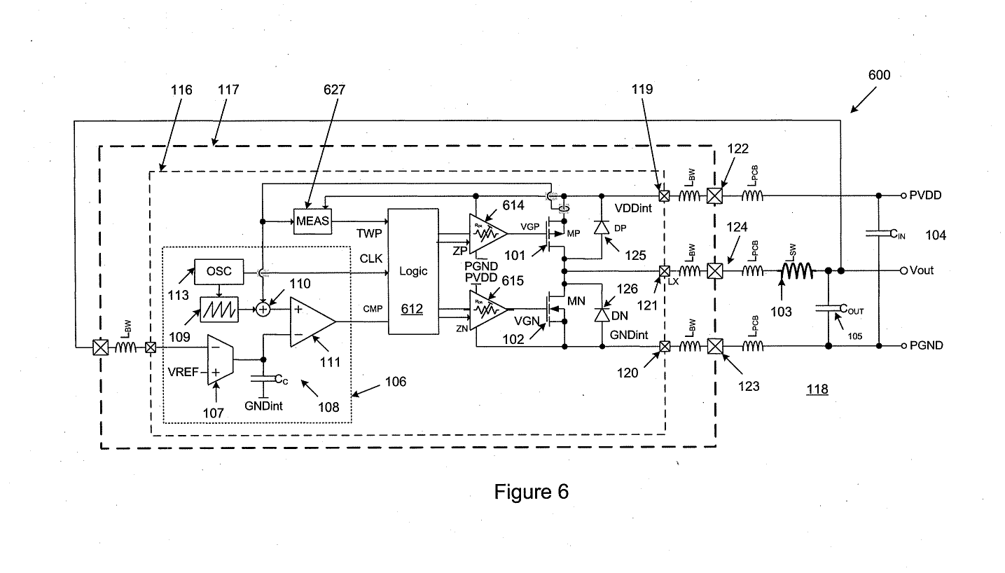

FIG. 6 illustrates an embodiment of a DC-DC step-down (buck) converter according to the present invention. Similar components to those described in relation to FIG. 1 are identified by the same numerals.

In the embodiment shown in FIG. 6 first and second power switches 101 and 102 are driven by variable strength pre-drivers 614 and 615, respectively. As the skilled person will appreciate a pre-driver is any circuitry that can control turn-on or turn-off of a power switch (the power switches themselves are sometimes known as drivers).

Both pre-drivers are shown as variable strength pre-drivers in FIG. 6 although it will be clear from the foregoing that in some embodiments only one of the pre-drivers may be a variable strength and that it may be only the pull-up, i.e. output that raises the gate voltage of the relevant power switch, or pull down, i.e. output that lowers the gate voltage of the power switch, of a pre-driver that has a variable strength.

By changing the drive strength of the pre-drivers 614 and 615 the turn-on and/or turn-off rate of the power switches can be altered. Increasing the drive strength increases the rate of change of power switch current as described above and thus reduces the turn-on or turn-off time accordingly.

As mentioned above, inductor current and/or supply voltage PVDD may be taken into account when setting the drive strength of the pre-drivers for the power switches. In the embodiment shown in FIG. 6 both are measured in measurement block 627 and fed to the logic 612. Logic 612 and variable strength pre-drivers 614 and 615 together comprise switch control circuitry for controlling the power switches. Logic 612 is responsive to the measurement block 627 to control the strength of the pre-drivers 614 and 615. Depending on the data fed to the logic 612 the drive strength of the pre-drivers for the power switches can be adapted to the present operating point.

The drive strength may be adjusted in a number of ways. As given above in Eqn. (3) the magnitude of the induced voltage spike or kick on the internal supply nodes is related to the rate of change of power switch current and the value of the parasitic inductances of the supply lines. If the lowest breakdown voltage of the PMOS power switch is V_{BV}, to avoid damage the sum of supply voltage PVDD plus ΔVP plus ΔVN should be less than V_{BV} (neglecting the effect of the diode voltage for simplicity). Assuming that the magnitude of ΔVN will be equal to that of ΔVP and equal to V_{L}) the minimum acceptable time dt=t₃−t₂ for the current change can be found from:

$$d t = d i \times \frac{L}{{V}_{L}} = {i}_{IND} \times \frac{L}{\frac{{V}_{BV} - {V}_{PVDD}}{2}} \qquad Eqn . ( 7 )$$

where L represents the sum of inductances of the bond wire and PCB between nodes 119 and input capacitor C_{IN} 104 and i_{IND} is the present inductor current. The value L may be assumed to be constant, although in practice it may be dependent on some additional independent operational parameters such as temperature, which could be taken into account in some embodiments if desired.

As can be seen from equation (7), the minimum transition time is proportional to the inductor current i_{IND}, and is proportional to the reciprocal of the breakdown voltage minus the supply voltage. i.e.:

$$d t ∝ \frac{{i}_{IND}}{( {V}_{BV} - {V}_{PVDD} )} \qquad Eqn . ( 8 )$$

The logic unit 612 may therefore receive the indication of inductor current and supply voltage and set the drive strength of the pre-driver (for at least the high-side switch 101 turn-off) based on equation (8). In other words the drive strength is adjusted such that the switch transition duration is proportional to the inductor current and inversely proportional to a constant minus the supply voltage. In this way if either the inductor current or supply voltage decreases the rate of switch transition can be increased.

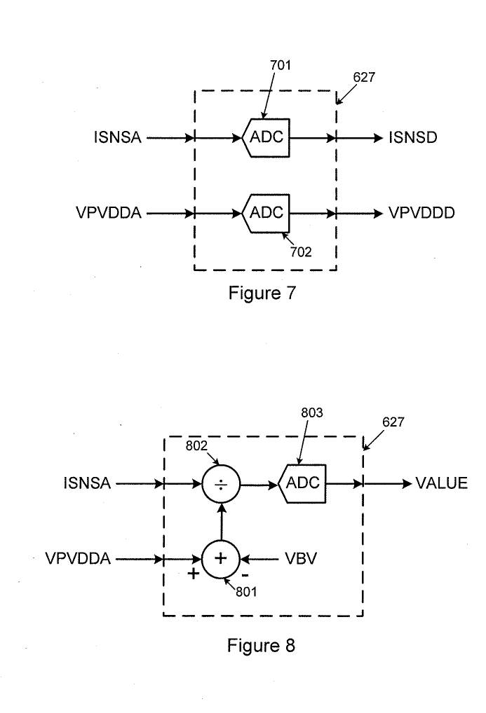

In the embodiment shown in FIG. 6, the measurement block 627 provides a digital signal to the logic block 612. One embodiment of measurement block 627 is shown in FIG. 7 wherein an analogue signal ISNSA indicative of the inductor current is received and converted into a corresponding digital signal ISNSD by analogue to digital converter 701 and an analogue signal VPVDDA indicative of the supply voltage is converted into a digital signal VPVDDD by analogue to digital converter 702. The digital signal passed to the logic block 612 would comprise both VPVDDD and ISNSD.

The analogue inductor current signal ISNSA may be provided by a current sensor, such as a sense resistor or circuitry which is monitoring the current through one or both of the power switches. The analogue inductor current signal may be in the form of a current, voltage or other representative signal: such a representative signal being a frequency signal for example. It will thus be appreciated that the current through the inductor (and the inductor node) may be determined by sensing the current flow through another circuit element. For a current mode converter such as shown in FIG. 6 an indication of inductor current is required as part of the control loop in any case and this current sense signal may also be provided to the measurement block 627. Thus no additional circuitry would be required to provide the inductor current signal. For a voltage mode converter there may be some measurement of output current for current limiting or other monitoring purposes and a current sense signal from such monitoring circuit may be used to provide an indication of inductor current.

A measurement of the real-time inductor current at the point of the switch transition would be most accurate. For instance, for a buck converter as shown in FIG. 6 the inductor current of interest for turn-off of the high-side switch is the peak inductor current. For turn-on of the high-side switch (or turn-off of the low-side switch) the inductor current of interest is the valley current. In some embodiments however a real time indication of the inductor current may not be available and an indication of the inductor current at one point in the cycle, e.g. the peak current, or an indication of average current may be used instead. Further, in some embodiments it may not be possible to adapt the drive strength based on an indication of current in the current cycle and thus a value of inductor current from a recent previous cycle may be used. The speed of change of the average inductor current is usually limited by the bandwidth of the DC-DC converter, and typically the bandwidth is a factor of 5 to 10 times lower than the switching frequency of the converter. Hence using a current indication from a previous cycle will not cause any problems.

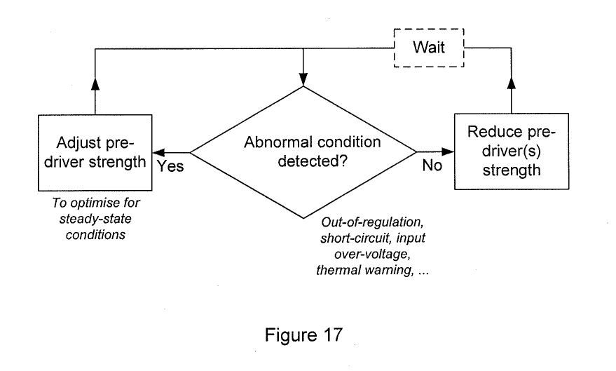

It should be noted that there may be occasions where the DC-DC converter will keep one of the power switches on for more than one switching period, e.g. under large load transient conditions. In case no accurate current indication is possible under these circumstances the drive strength can be set to a safe value that will make sure that the inductive voltage spikes stay below a value that guarantees safe operation under all circumstances. The drive strength may be set to a safe value immediately on detection of loss of a valid current signal, and may be allowed to recover to a higher value only after a predetermined time-out (say 256 ms) after a valid current signal is recognized. Similarly other fault modes may be detected and cause immediate setting of pre-driver strength to a safe value and only allowed to recover to a stronger value after a similar timeout. FIG. 17 shows a flow chart indicating operation of switch control circuitry for controlling the pre-drivers with a default safe drive strength level. Examples of faults conditions include output short-circuit and input over-voltage spikes (e.g. from external EMI pulses). A similar time-out may be imposed to filter out the effects of short under-voltage spikes on the supply, to avoid similarly short-duration modulation of the pre-driver strength, which would have negligible impact on long-term average power losses.

The signal VPVDDA indicative of supply voltage may simply comprise the supply voltage, level shifted or scaled as appropriate, for conversion to a digital value. The signal VPVDDA may be in the form of a current, voltage or other representative signal: such a representative signal being a frequency signal for example.

The current and voltage signals may thus be converted independently and the individual digital values delivered to the logic 612 to be used to set the drive strength of the pre-drivers.

In its simplest implementation this comparison may merely be a one-bit conversion, i.e. a comparator for one or both inputs. For instance, if the input supply is known either to be a USB bus supply at 4.5-5.5V or a battery at nominally 3.7V it may be enough merely to have a threshold at say 4V, with a switching speed designed to cope with 5.5V or 4.0V respectively. In other embodiments, however, higher bit conversions may be performed with the result that a range of different drive strengths of pre-drive may be set. In essence the current and/or voltage signal may be compared to at least one threshold in order to derive a control signal for the pre-drivers.

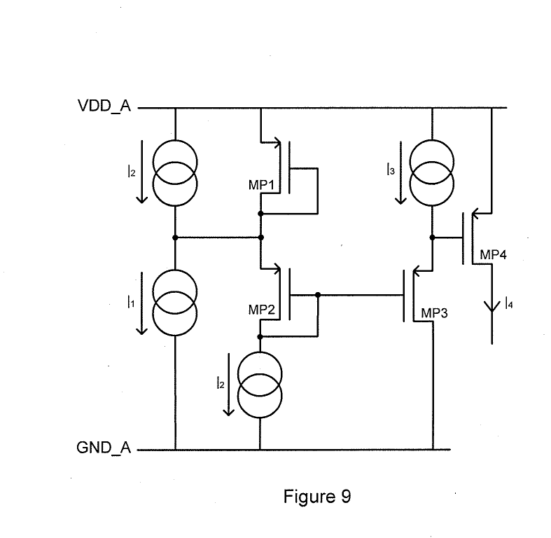

FIG. 8 shows an alternative embodiment of measurement block 627. In this embodiment the current and voltage information are combined in the analogue domain according to the proportionality equation (8) above. The signal VPVDDA indicative of the supply voltage may be combined in a summation node 801 with a negative reference signal VBV which represent the breakdown voltage. The resultant signal is input to a divider node 802 with the current signal ISNSA. The combined value is then converted into the digital domain by ADC 803. If the current and voltage information are both available in the current domain then they may be easily combined in a translinear circuit that implements the proportionality equation. FIG. 9 shows an embodiment of a suitable translinear circuit.

If all of the transistors in the circuit in FIG. 9 operate in weak inversion it can be shown that

I_{MP1}×I_{MP2}=I_{MP3}×I_{MP4}. Eqn. (9)

The equation above can be rearranged to yield:

$${i}_{MP 4} = \frac{{I}_{MP 1} \times {I}_{MP 2}}{{I}_{MP 2}} . \qquad Eqn . ( 10 )$$

If the respective currents are set such that I_{MP1}=i_{IND}, I_{MP2}=1 and I_{MP3}=(I_{VBV}−I_{VPVDD}), where I_{VBV} and I_{VPVDD} are current domain representations of V_{BV} and V_{PVDD}, the result is:

$${I}_{MP 4} = \begin{matrix}{i}_{IND} \\ ( {I}_{VBV} - {I}_{VPVDD} )\end{matrix} . \qquad Eqn . ( 11 )$$

I_{MP4} can be converted into the digital domain and used by the logic 612 to set the drive strength of the pre-drivers of the power switches. In practice however the currents I_{MP1} etc. may be scaled versions of the respective currents, to provide currents of lower magnitude for processing with smaller devices and low power consumption.

In the embodiment shown in FIG. 6, the logic 612 takes the digital value(s) delivered by the measurement block 627 and translates them into control words for the pre-drivers. It also ensures that the control words are synchronised to the clock so that the drive strength is modified at the appropriate time of the switching cycle. The translation of the digital value(s) of the measurement block 627 into a control word for the pre-drivers can conveniently be implemented by a look-up table.

In some embodiments however measurement block 627 may not be required, where an indication of inductor current demand and/or input supply voltage may be determined by other circuitry of the host device (i.e. of the system, apparatus, or device incorporating the DC-DC converter) and provided to the DC-DC converter. This could comprise monitoring circuitry elsewhere in the host device.

In one embodiment the operating conditions or mode of the host device/system may be used as an indication of the input supply voltage and/or inductor current. For example if a host device may be powered via a mains adapter or via a battery, detection that a mains power source is connected may be used to determine that the input supply voltage is a high level whereas if the power source is the battery the input supply voltage may be determined to be a low level. A signal line indicating whether or not power is being received via a mains adapter may therefore be used as an indication of the supply voltage. Similarly, for a boost converter a control signal selecting a voltage output may be used as an indication of the voltage output.

The inductor current of the converter is also, at least partly determined by the load current demand of the host device. The load current demand clearly depends on the operation of the host device, for example the active sub-systems of the host device and the demands thereon. The load current demand, or an activity level of the host device, may therefore be used as an indication of inductor current. For instance, a host processor may be adapted to vary its processing frequency based on the processing demands on it. A greater processing demand will lead to an increased processing frequency with a consequent increase in current demand, especially if the processor supply voltage is also increased. A signal indicative of processor speed, i.e. frequency, and/or voltage or some other control signal from a host processor may therefore be used to set the rate of turn-on or turn-off of a power switch. Such as signal may comprise details of the actual values of processor frequency and/or voltage or just relative levels of activity: high, medium or low for example.

In some embodiments therefore, in use, the logic unit may receive control signals from other parts of the host device indicative of input supply voltage, current demand and/or activity level and set the driver strength of the pre-driver for the appropriate switch transition accordingly. FIG. 22 illustrates a device i.e. host device, 2200 comprising a power management module 2201 which comprises a DC-DC converter 2202 which has a battery 2203 as a possible power source for the DC-DC converter 2202. The DC-DC converter 2202 supplies power to a variety of sub-systems of the host device 2200, including a processor 2204. The processor 2204 may provide a control signal 2205 to the DC-DC converter regarding the operating level or mode of the device/system and the DC-DC converter 2202 may use said control signal to set the rate of turn-on or turn-off of a power switch of the converter. As described above the control signal 2205 may be an indication of processor frequency and/or voltage and/or an indication of a particular mode, such as high demand video processing mode or a low demand audio mode for example. The device may also be able to receive power from an external power supply 2206 via an input terminal 2207. The external power supply 2206 may be a mains adapter or USB power supply or the like and some devices may have multiple inputs for different power supplies. The 2204 may detect the presence of such an external power supply 2206 via a signal line 2208 and indicate an appropriate voltage level for instance to the DC-DC converter 2202. Alternatively the power management module 2201 or DC-DC converter 2202 may directly detect the presence of the external power supply 2206, e.g. from signal line 2208. Additionally other circuitry 2209 of the host device may detect the presence and/or voltage level of an external power supply and/or any changes in operating mode and send a suitable control signal 2210 to the processor 2204 or directly to the power management module 2201 or DC-DC converter 2202.

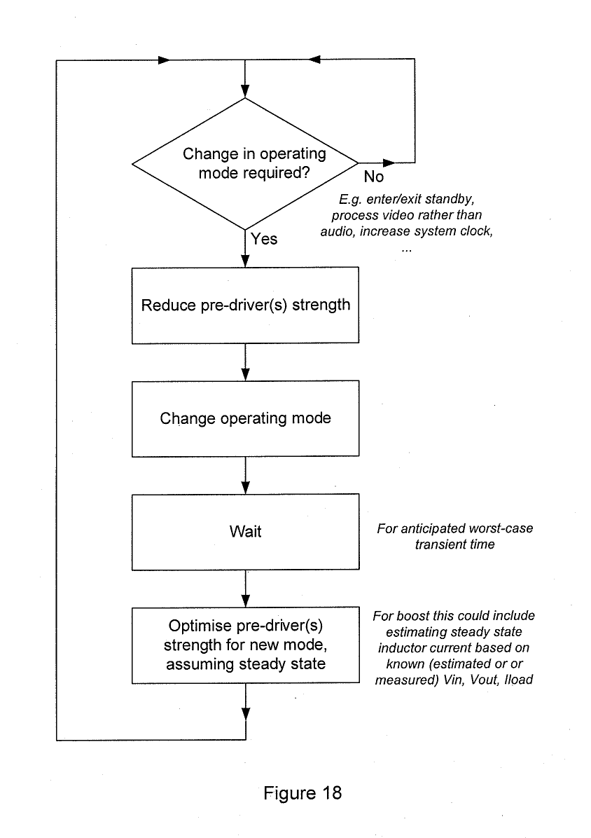

Any anticipated changes in operating mode of the host device 2200 that could lead to an increased stress on the power switches during the change in operating mode may be communicated to the switch control unit of the DC-DC converter 2202 to cause it to immediately reduce the pre-driver strength to a minimum or other calculated safe value. FIG. 18 shows a flow chart illustrating operation of switch control circuitry in such circumstances. For example if the host device has been in a sleep mode and is woken up or has been performing a relativity low demand activity (e.g. audio processing and playback) and is requested to start a relatively high demand activity (e.g. video processing), the host device may provide a control signal indicating the change in activity level/operating mode. The rate of turn-on and turn-off of the power switches is then set to a default safe operating level (or reduced by set amount) during the change in mode to allow for any transients. Only after a time-out would the logic unit be allowed to set the pre-driver strength to a more optimum value, based on steady-state operation, possibly with margin for any later less severe transients.

Referring back to the embodiment shown in FIG. 6, the pre-drivers for the power switches receive the control word from the logic 612. The control word is used to set the drive strength of the pre-drivers.

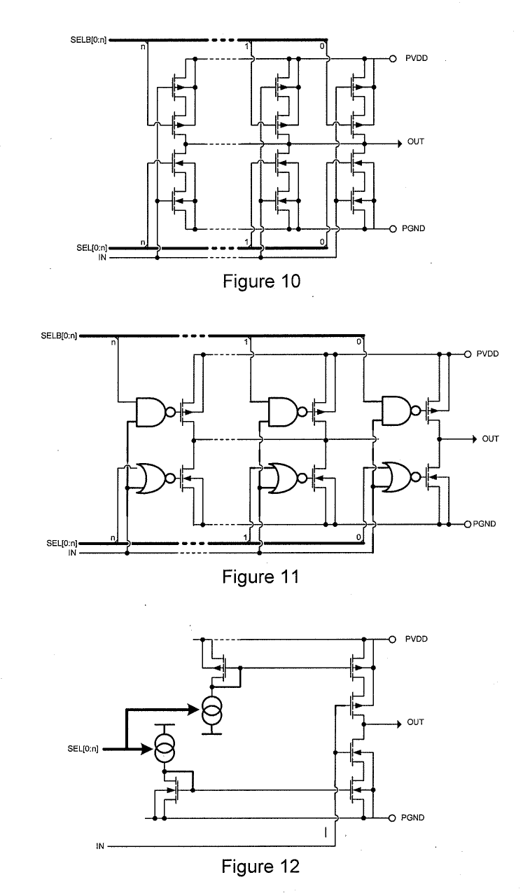

FIG. 10 shows an embodiment of a programmable drive strength inverter, i.e. pre-driver. The pre-driver comprises a plurality of driver stages. The drive strength is selected by bits of the control word SEL and its inverted word SELB which turn on or off respective pass transistors tied between the pre-driver output node and respective pre-driver output transistors. As can be seen the inverters that have been selected do contribute towards driving OUT, whereas the inverters that have not been selected are put into a high-impedance state and so do not contribute. The individual inverter stages can be of equal drive strength or different drive strengths and may be selected by a logic arrangement. In a variation of this embodiment the pass transistors and pre-driver output transistors may be swapped. In a further variation, some of the pass devices may be replaced by direct connections, for example if only the pull-up is to be programmable, all the low-side pass devices may be replaced by direct connections.

FIG. 11 shows an alternative embodiment of a programmable drive strength inverter. The pre-driver again comprises a plurality of driver stages. The drive strength is selected by the control word SEL and its inverted word SELB, by gating the drive to respective output transistor gates, to turn off unselected pre-driver output transistors. As can be seen the inverters that have been selected do contribute towards driving OUT, whereas the inverters that have not been selected are put into a high-impedance state and so do not contribute.

FIG. 12 illustrates the principle of further alternative embodiments of a programmable drive strength inverter. A pre-driver output stage inverter is connected to supply and ground via pass transistors, but these pass transistors are driven with reduced gate-source voltages to restrict the maximum current flowing to the output. The reduced gate voltages may be generated by a current mirror arrangement. The input current to the current mirror may be programmable digitally. Alternatively the input current may be derived from analog signal processing of signals based on the operating voltage and/or current.

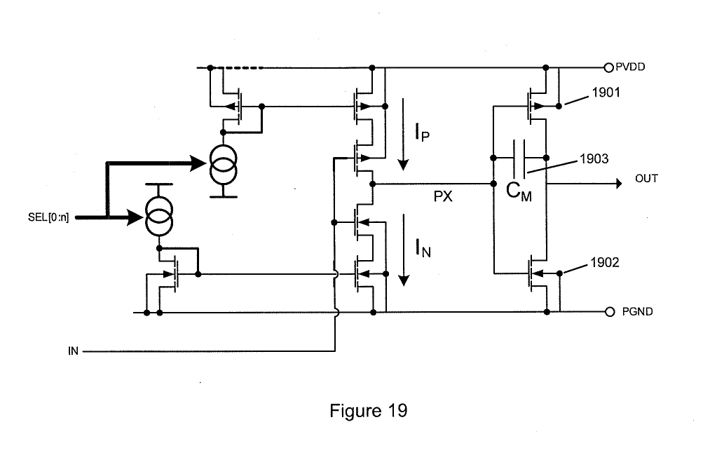

FIG. 19 shows another embodiment of a pre-driver circuit for driving a power switch. The rate of turn-on or turn-off of the power switch is varied by altering the slew rate of the signal applied to the power switch gate. The pre-driver circuit is connected to the power switch via an intermediate inverter stage comprising a PMOS 1901, an NMOS 1902 and capacitor CM 1903. When a signal on input IN is low, the first stage supplies a current I_{P} to pull up node PX and thus pull down node OUT (connected to the power switch). However once PX reaches near the switching threshold of the inverter, while OUT is slewing from PVDD to PGND, the inverter is in a high gain state, so the capacitor CM 1903 acts like an amplifier Miller capacitor. Thus node PX moves only slowly and the current I_{P} is used to charge up the Miller capacitor, giving a slew rate on V_{OUT} of I_{P}/CM, until OUT is near ground. Thus the turn-on or turn-off rate of a power MOS connected to OUT is controlled by I_{P}, i.e. by the digital bits SEL[0:n] that control IP. Similarly, the other edge of OUT is controlled by SEL[0:n] via IN.

It will be apparent that node PX could alternatively be controlled by other means for controlling the current I_{P} (or the current I_{N}) or PX could itself by driven by a variable strength pre-driver, such as those described previously.

Further variations and combinations of the above schemes will be evident to persons skilled in the field.

Using such programmable strength pre-drivers the rate of at least one transition of a power switch can be controlled as described based on the operational conditions of the converter so that the switch may operate as fast as possible, to reduce power losses, but without exceeding safe operating voltage levels.

For a consideration of the efficiency savings possible consider a buck converter as shown in FIG. 6 and assume that the maximum recommended operating voltage of the converter (i.e. maximum supply voltage PVDD) is 5.5V and that the lowest of any of the breakdown voltages of the power switches, V_{BV} is 8V. This means that the maximum additional voltage that can be tolerated due to inductive voltage spikes during a switch transition is 2.5V. Assume further that the maximum load current of the step-down current is 2.5 A and that the sum of the bond wire and PCB inductances is 1.5 nH on the PVDD and PGND terminals 119 and 120 each.

Using equation (7) the minimum safe time during which the PMOS switch current can go from 2.5 A to 0 (and vice versa on the ground supply line) is therefore given by:

$$d t = d i \times \frac{L}{{V}_{L}} = 2.5 A \times \frac{1.5 nH}{\frac{( 8 V - 5.5 V )}{2}} = 3 ns . \qquad Eqn . ( 12 )$$

For a conventional converter the pre-drivers would therefore be designed to ensure at least a 3 ns duration of current change so that operation at these maximum conditions would not exceed the safe operating area. However the rate of switch transition (i.e. turn-on or turn-off) would not be variable.

Referring back to equation (6) the resulting switch transition losses, assuming a switching frequency of 2 MHz and assuming for simplicity that the periods between t₁ and t₂ and between t₂ and t₃ are equally long, will be:

P_{SWC}=½×5.5V×2.5 A×(3 ns+3 ns)×2 MHz=82.5 mW. Eqn. (13)

For a DC-DC step-down converter that generates an output voltage of 1.2V this equates to an efficiency drop due to switch transition losses of 5.2%.

If the load current drops to only 100 mA, but the switch transition speed is not changed, as per a conventional converter, the resulting power loss due to switch transition losses is 3.3 mW which still represents an efficiency drop of 5.2%.

However in this instance, with the peak inductor current reduced to 100 mA, the inductive voltage spikes at the supply nodes 119 and 120 are now:

$${V}_{L} = L \times \frac{d i}{d t} = 1.5 nH \times \frac{0.1 A}{3 ns} = 50 mV \qquad Eqn . ( 14 )$$

This is well below the upper limit of overall 2.5V that are possible without damaging any of the circuitry.

Embodiments of the present invention therefore vary the rate of switching based on the change in current. Under these new operating conditions, the maximum switching speed, from equation (7), is 0.12 ns. If the switching speed for PMOS turn-off is therefore increased by appropriately adjusting the pre-driver strength, such that the current change occurs in 0.12 ns, the resultant switch transition losses fall to 0.13 mW which represents an efficiency loss of only 0.2%.

This suggests that by varying the rate of turn-off of the PMOS switch when the (peak) load current drops from 2.5 A to 100 mA an efficiency saving of greater than 5.0% can be made.

The analysis above concentrated on a change of inductor current only. Consider now that the supply voltage changes, for example the supply voltage drops to 3.7V instead of 5.5V. If operating at the maximum load current of 2.5 A, using the safe switching speed of 3 ns duration for the current change would give an efficiency loss of 3.6%.

However with the supply voltage reduced to 3.7V the total voltage spike that can be tolerated across the inductive elements is 4.3V. At the maximum 2.5 A load current that would mean that the minimum duration for the current to change from 2.5 A to 0 and vice versa could be 1.7 ns.

If the switch transition was therefore adjusted so that the current change did occur in 1.7 ns the resulting power loss is 32.2 mW or an efficiency loss of 2.1%. Thus under maximum current load conditions taking the variation in supply voltage into account in setting the switching speed can provide an efficiency saving of 1.5%.

The embodiments have also been described mainly with reference to buck converters. It will of course be apparent that the principles of varying the rate of turn-on and/or turn-off of at least one power switch apply to various other types of converters. For instance the same general considerations apply to boost converters and to buck-boost converters.

For a boost converter, however, the output voltage will be larger than the input supply voltage and thus the maximum voltage stress on the power switches will generally be defined by the output voltage rather than the input voltage. Therefore the rate of switch transition may take the output voltage into account. For some boost converters the output voltage may be fixed and thus there will be no need to vary the switching speed based on output voltage. In such boost converters efficiency gains can still be made however by adjusting the rate of switch transition for at least some transitions based on the inductor current. However if the output voltage of the boost converter is variable then similar considerations as for the supply voltage in a buck converter apply.

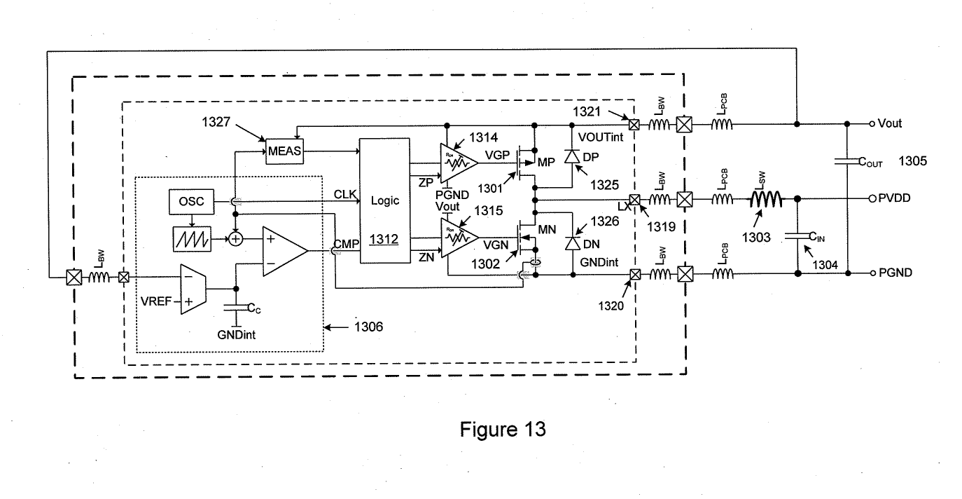

FIG. 13 shows an embodiment of a DC-DC boost converter circuit according to the invention. This includes similar components to FIG. 6, but with some changes in their interconnections. For example, PVDD and Vout and their respectively associated capacitors are swapped; also the inductor current is shown as being sensed at the NMOS source, not the PMOS, as would be more usual for a boost converter.

The high-side switch 1301, in this case a PMOS switch, is coupled between the output supply node 1321 (connected to Vout) and a switched inductor node, LX. A low-side switch 1302, in this case an NMOS switch, is connected between the switched inductor node LX and a low-side supply node 1320 (connected to PGND). An inductor 1303 is connected between the common inductor node LX and the input supply terminal PVDD. An input decoupling capacitor 1304 is connected between the input supply and ground supply and an output smoothing capacitor 1305 is connected between the output and ground supply.

Servo control circuitry 1306 receives a feedback signal from the output voltage in a similar fashion as described above in relation to the buck converter and thus will not be described further.

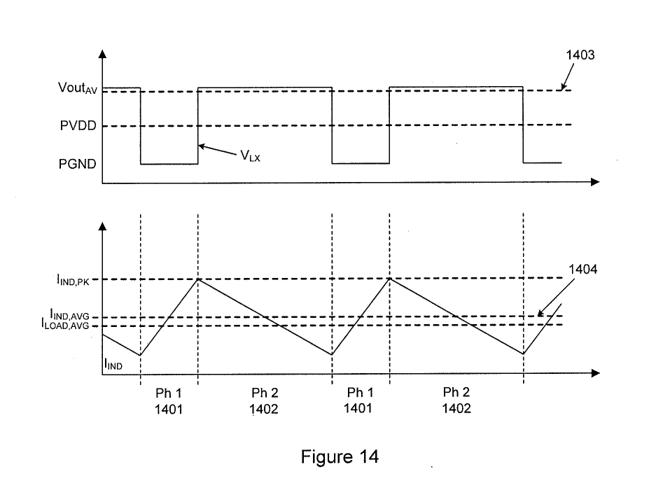

FIG. 14 shows typical voltage and current waveforms for a DC-DC converter such as that of FIG. 13 in a typical step-up, i.e. boost converter switching cycle in continuous conduction mode. The upper plot illustrates the voltage at node LX and the lower plot illustrates the inductor current. During one phase 1401 of the switching cycle the low-side power switch 1302 is closed, i.e. on, and the voltage at node LX is near ground and the inductor current (from PVDD to LX) increases. During another phase, 1402, the low-side switch 1302 is off and the high-side switch 1301 is closed (on). In this phase the voltage on LX flies high to near VOUT and the inductor current decreases (due to the polarity of the voltage across the inductor) while the inductor charges up the output smoothing capacitor and supplies current to the load. (In detail there will be some ripple or switching spikes on the actual output voltage Vout, so the vertical axis is labelled with a level Vout_{AV} representing the average or nominal value of the output voltage waveform at Vout).

The duty cycle of the two switching phases are controlled by the logic 1312 based on the error signal to generate the required average output voltage Vout_{AV}. The average output voltage Vout_{AV} average inductor current, I_{IND,AVG} and average output current I_{LOAD,AVG} are indicated in FIG. 14 by dotted lines 1403, 1404, and 1405 respectively. Note for this buck converter the inductor is always connected to the high-side supply PVDD, so its average current I_{IND,AVG} is equal to the average input supply current, not the average output current I_{LOAD,AVG}, since the inductor is only connected to the load for part of each cycle.

As with the buck converter described with reference to FIG. 1, in practice the boost converter may be implemented as an integrated circuit within a package on a printed circuit board (PCB) for example. FIG. 13 also illustrates parasitic inductances L_{BW} and L_{PCB} similar to those discussed above in relation to FIG. 1.

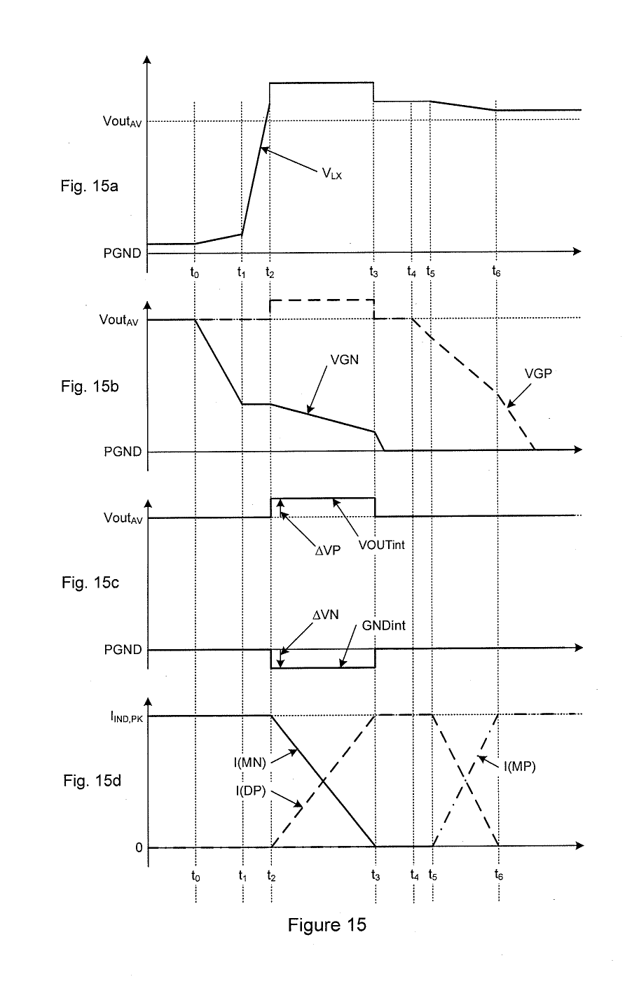

FIG. 15 illustrates voltage and current waveforms during a switching transition from phase 1301 of FIG. 14, where the high-side switch 1301 (e.g. PMOS) is off and the low-side switch 1302 (e.g. NMOS) is on, to phase 1302 where the high-side switch is on and the low-side switch is off.

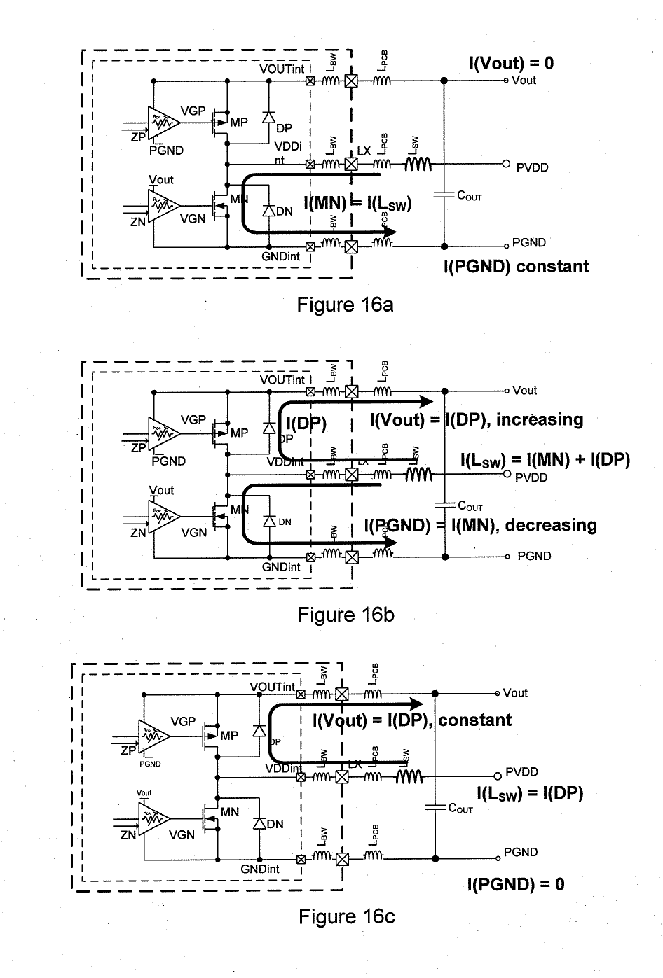

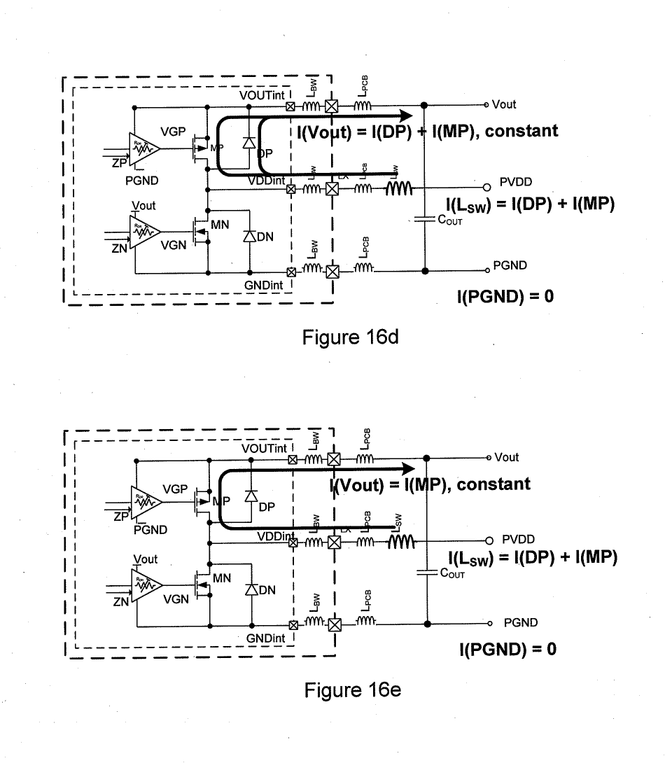

FIG. 15a illustrates the voltage V_{LX} at node LX during the transition (relative to the external ground) and FIG. 15b shows the gate voltage, VGP, of the PMOS switch 1301 and the gate voltage, VGN, of the NMOS switch 1302. FIG. 15c illustrates the voltages developed at the ground supply node 1320 and output supply node 1321 of the DC-DC converter. FIG. 15d shows the current, I_{MP}, through the PMOS switch 1301 the current, I_{MN}, through the NMOS switch 1302 and also the current, I_{DP}, through a diode 1325 associated with the PMOS switch. FIG. 16 illustrates the current flow through the output components at different stages of this transition.

Before the transition begins the NMOS switch 1302 will be carrying all the inductor current, as illustrated in FIGS. 16a and 15d. The inductor current will be ramping up, as described with reference to FIG. 14 above, but over the timescales shown in FIG. 15 the ramping will be too small to be noticeable. The voltage at node LX, as illustrated in FIG. 15a, will be PGND plus a small voltage mainly due to the on resistance of the NMOS switch. For a conventional NMOS switch the gate voltage VGN will, in the example illustrated, be Vout and the NMOS will be hard on. It should be noted that FIG. 13 shows both pre-drivers 1314 and 1315 being connected to Vout and PGND and thus FIG. 15b shows the gate potentials varying between Vout and PGND. Such an arrangement may be used in many applications, for example, when PVDD is supplied by a single cell battery and the output is boosted to 3V. It will be appreciated however that other arrangements for the pre-drivers are possible are may be used in other applications. For instance for a DC-DC boost converter used as backlight supply the pre-driver 1315 for the NMOS switch may be driven by PVDD and PGND and the pre-driver 1314 for the PMOS switch may be driven between Vout and Vout-PVDD or a similar arrangement.

At a time t₀ the transition begins and the gate voltage VGN of the NMOS switch starts falling towards PGND. At first, when the gate voltage VGN starts falling, the NMOS switch will still be able to carry the required current with only a slightly increasing on-resistance as the NMOS gate-source voltage reduces in magnitude, until, at time t₁, the gate voltage VGN has fallen to a point where the NMOS gate-source voltage has reduced so much that the transistor cannot sustain the current anymore, at least with the small Vds existing at this time.

At this point the voltage at node LX then rises rapidly (at this point in the cycle, most of the current delivered from the pre-driver is used to charge the gate-drain capacitance of the NMOS rather than the gate-source capacitance, so the rate of change of VGN slows down). Eventually, as the gate voltage VGN continues to fall, the NMOS switch is unable to supply the required current even with the full supply voltage between the NMOS drain and source. During this example switching cycle the PMOS switch is not turned on until the NMOS switch is fully turned off to avoid a shoot-through condition. So the PMOS switch cannot supply the remainder of the current demanded by the inductor. The voltage at node LX rise above VOUT and starts to forward bias the diode 1325 associated with the PMOS switch in order to source the remainder of the current. In a similar fashion as discussed above with reference to FIG. 1 the PMOS switch will have an associated diode 1325 and the NMOS switch will have an associated diode 1326. These diodes may be intrinsic or external as discussed above.

The voltage at node LX thus rises above VOUT and starts to forward bias diode 1325. At this point, t₂, the current through the NMOS switch starts to decrease and ramps down to zero whilst the diode 1325 takes an increasing share of the inductor current as illustrated in FIG. 16b.

This increasing current on the Vout output line induces a voltage kick for the same reasons as described above. The polarity of this voltage kick, as will be described in more detail below, causes an increase in the voltage at the output node VOUTint. The voltage at LX, being clamped at a diode voltage above the voltage at the output node also experiences this voltage kick (relative to the external ground).

It will be noted that at this time, as the voltage at node LX is higher than PVDD the inductor current will actually be decreasing. However again this change will be small on the timescales shown in FIG. 15.

As its applied gate voltage VGN decreases further, the current through the NMOS switch decreases, whilst the current through diode 1325 increases until, at t₃, the NMOS switch current reaches zero and at this point all the inductor current is flowing through the diode 1325, as illustrated in FIG. 16c.

As mentioned, during the period between t₂ and t₃ the current through the NMOS switch (from LX to PGND) is decreasing rapidly. This will cause a noticeable negative kick or spike in voltage on the internal supply node GNDint 1320 due the parasitic inductances associated with the ground, L_{GND}, where L_{GND}=L_{BW}+L_{PCB} for the supply line. This voltage change, ΔVN, will be given by:

$$Δ VN = {L}_{GND} \times \frac{d I ( MN )}{d t} \qquad Eqn . ( 15 )$$

As the current is decreasing but the current flow is towards ground the polarity of this voltage kick is to make the voltage at internal supply node GNDint 1320 more negative.

Similarly, the equally quick rise in current though the parasitic inductances L_{Vout} in the output path will give rise to a positive voltage kick on the internal output supply node VOUTint of magnitude ΔVP:

$$Δ VP = {L}_{Vout} \times \frac{d I ( MN )}{d t} \qquad Eqn . ( 16 )$$

Once the current through the NMOS switch reaches zero at t₃ the currents through the low-side supply and output supply lines will be constant (on the timescales of FIG. 15) and thus both voltage differences will recover to zero.

At a time t₄ the turn-on of the PMOS switch 1301 begins. The magnitude of the gate-source voltage of the PMOS is increased and, once a threshold is reached at time t₅, the PMOS switch starts conducting, as illustrated in FIG. 16d. As the gate drive of the PMOS switch ramps up it takes an increasing amount of the current from the diode 1325 until, at time t₆, the PMOS switch is providing all the required current and no more current is flowing through the diode 1325, as illustrated in FIG. 16e. The PMOS switch 1301 is now fully on. During the PMOS switch turn-on the total current flowing through the output path is essentially constant (and the current through the ground line is zero) and hence there is no voltage kick on the internal nodes during this transition.

It should be noted that FIGS. 15 and 16 show the PMOS switch only beginning to turn-on after the NMOS switch current has dropped to zero. The skilled person will appreciate that the PMOS switch may be turned on at any time after the voltage at node LX has risen above VOUT in order to reduce the amount of time where conduction is via diode 1325. However the principles will be the same—the diode 1325 will take a share of the current until the PMOS switch has turned on to a sufficient extent to provide all the required current. The transfer of current from diode to PMOS does not (to first order) affect the total ground current ramp rate, which is still defined by the NMOS switch current ramp rate, so the voltage kick will persist until t3 and will be unaffected by PMOS turn-on rate.

Analogously to the buck converter case, there is a trade-off between switch transition power losses and voltage stress on a power switch, via the rise time of the power-switch pre-drive and the resultant inductive kicks on internal nodes. In this case it is the possible breakdown of the NMOS power switch that is of concern, rather than the PMOS power switch, and its voltage stress is dependent on the output voltage VOUT rather than the supply voltage PVDD.

The opposite transition where the PMOS switch turns off and the NMOS switch turns on, the inductive kick (which only occurs when the NMOS switch turns on) is such as to decrease the device stress, so there is not the same tradeoff, providing the inductor current remains in the same direction.

The discussion above has considered a positive load current, i.e. with a current flowing from the output supply node 1321 towards the load, and hence a current flow from the inductor towards the internal inductor node 1319. In some instances however the load current can reverse (similarly to the buck converter cases) and in which case the NMOS switch turn-off may not lead to any induced voltage kick. The polarity of the inductor current or load current may therefore also be used in controlling the rate of turn-on or turn-off of the power switches, e.g. the PMOS switch turn-off time may be varied. The skilled person would be aware of the switch transitions that could useful be controlled to reduce switch transition losses in such a case.

Both pre-drivers 1314 and 1315 are shown as variable strength pre-drivers in FIG. 13 although it will be clear from the foregoing that in some embodiments only one of the pre-drivers may be a variable strength and again it may be that only the pull-up or pull-down pre-driver strength may be variable. The implementation of these pre-drivers may be similar to those described above with respect to the buck converter.

As mentioned above, inductor current and/or output voltage VOUT may be taken into account when setting the drive strength of the pre-drivers for the power switches. The embodiments of switch control circuitry and pre-drivers described above with respect to FIGS. 7 to 12 can be applied equally to the boost converter embodiment described although the reference to a voltage signal VPVDDA will be taken to mean an indication of the output voltage. The inductor current can be measured by any suitable means, such as current sensor or by monitoring the current through the PMOS switch and/or the NMOS switch as described above. Again whilst an indication of the real-time inductor current at the time of switching would be the most accurate, it is sufficient to use an indication of the inductor current at a certain point in the cycle or an average inductor current or a current determined in a recent previous cycle.

As for the buck converter, any fault conditions such as loss of current signal during large transients could be handled by immediate weakening of the pre-driver strength, with a timeout after recovery before the pre-driver strength is allowed to be increased. Similarly if the pre-driver strength is modulated in a more “open-loop” fashion based on external indications of the host device operating mode, transients that may increase stress on the power switch may be handled by immediate weakening of the pre-drivers, with any increase in pre-driver strength delayed until after the transient is anticipated to be or detected to be complete.

If information on load current rather than inductor current is available, the inductor current value used to derive the allowable pre-driver strength may be calculated in terms of the duty cycle corresponding to the steady state input and output voltages. Transients may temporarily alter the duty cycle and the power switch stress: such transients may be anticipated (e.g. those caused by changes in host operating mode) or may be detected by circuitry and may cause an immediate reduction in pre-driver strength, with recovery to the values consistent with steady-state behaviours after a timeout.

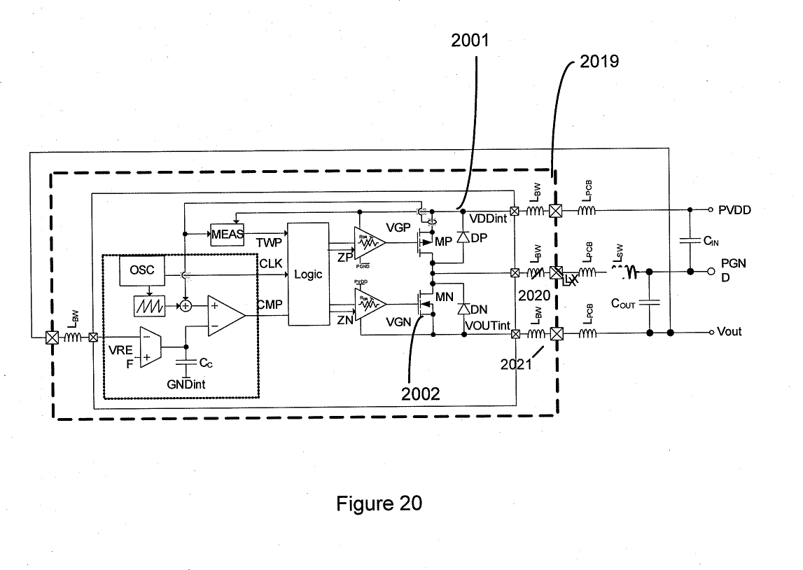

FIG. 20 shows an embodiment of a DC-DC inverting converter circuit according to the invention. This includes similar components to the buck converter of FIG. 6, but with some changes in their interconnections. For example, PGND and Vout are swapped—with a consequent change in the linking of the input capacitor.

The high-side switch 2001 is, in this converter connected between a high-side supply node 2019 and the inductor node 2020 and the low-side switch is connected between an output supply node 2021 and the inductor node 2020. In use the inductor is connected between the inductor node 2020 and the low-side (ground) supply PGND. Note that the terms high-side and low-side as used in relation to this inverting converter are taken to refer to high-side and low-side relative to the input supply voltages only (whether positive or negative). It will be appreciated that if one of the supply voltages is ground the output voltage will be of a different polarity to the other input supply voltage and, depending on operation, may be of a greater or lower magnitude. For the purposes of explanation however the term high-side will be taken to mean the high-side input voltage (whether positive or negative).

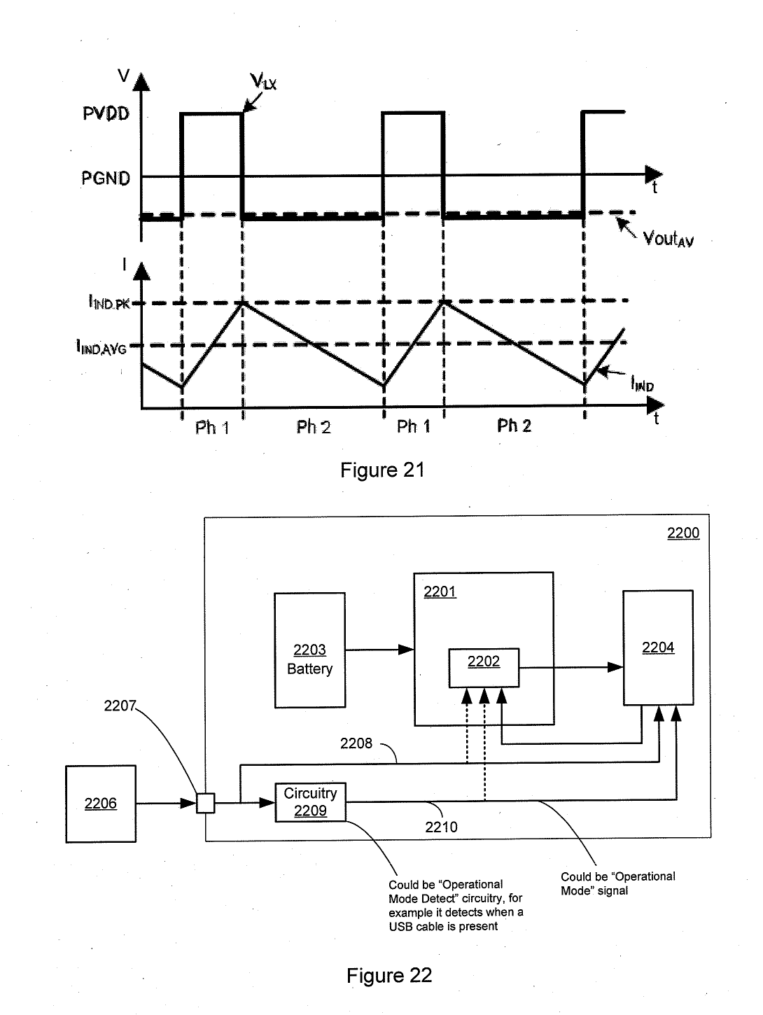

FIG. 21 shows typical voltage and current waveforms for such an inverting DC-DC converter as shown in FIG. 20 in continuous conduction mode. The upper plot illustrates the voltage at node LX and the lower plot illustrates the inductor current. It can be seen that during one phase (Ph1), the high-side switch 2001 is closed and the voltage at node LX flies high and the inductor current increases. During the other phase (Ph2) however the voltage at node LX drops to the output voltage which is negative and the inductor current decreases.

A detailed analysis of the switching transitions for such a converter will not be described but it will be clear that the same general considerations apply and that the rate of turn-on and/or turn-off of at least on of the power switches may be controlled based on the operating conditions of the converter (typically this will comprise controlling the rate of turn-of the high-side switch when the current flow is from the inductor node 2020 towards the inductor).

For this embodiment of converter the operational conditions of interest may comprise the magnitude and/or direction of the inductor current as described above in relation to the other embodiments. At least one supply voltage may also be taken into account. It will be clear that the maximum static voltage difference across the switches in this embodiment is equal to the magnitude of the output voltage, Vout, plus the magnitude of the input supply voltage PVDD. Thus both supply voltages may be taken into account, although if one or both of the input supply voltage and the output supply voltage is fixed, only an indication of a varying supply voltage may be needed in order to set the rate of turn-on or turn-off.

In general therefore for any DC-DC converter having a high-side switch connected between a high-side input/output supply node and an inductor node LX and a low-side switch connected between the inductor node and a low-side input/output supply node with each switch having an associated diode which is unidirectional towards the high-side supply node (such shown in FIG. 6 or 13) then it can be seen that a switch transition that involves a transfer of current from one of the power switches to its associated diode or vice versa will not induce any voltage kick in the supply lines connected to the high and low supply nodes as there is no change in the current flowing through such supply lines. It can also be seen that a voltage kick will be induced in transitions that involve a change in current path from one of the power switches to the diode associated with the other switch or vice versa.

Such a voltage kick will add to the voltage stress on the power switches, i.e. cause the voltages at the high and low supply nodes to move apart, if the current flow from the high-side node to the inductor node decreases, or alternatively become more negative (i.e. the current flow from the inductor node to the high-side node increase) or if the current flow from the low-side node to the inductor node increases (or a current in the opposite direction decreases). It can be seen from the foregoing that such conditions only occur for the converters described with reference to FIGS. 6 and 13 when a switch is turned off. For the buck converter, when there is positive current flow to the load, this occurs when the PMOS switch 101 turns off and so the high-side current to the inductor decreases and the low-side current to the inductor (via the diode 125 associated with the NMOS) increases. For the buck converter with negative current, i.e. current flowing away from the load, this occurs when the NMOS switch turns off and the current towards the low-side node decreases and the current towards the high-side node increases. For the boost converter this occurs when the NMOS switch turns off and the current from the low-side node to the inductor node decreases and the current from the inductor node to the high node (Vout) increases.

It can also be seen that, for this general type of DC-DC converter arrangement, that transitions involving turn-on of a switch and which involve a transfer of current away from the diode associated with the other switch will therefore result in a voltage kick that will bring the voltages at the high and low supply nodes closer together. As mentioned above however other effects such a ringing may be related to the rate of current change during these transitions and therefore it may be desirable to adjust the rate of turn-on of the switch accordingly for turn-on of some of the power switches.

The embodiments discussed above have been described mainly in terms of synchronous DC-DC switch-mode converters having two power switches, where efficiency savings may be important. DC-DC converters having a single power switch and a switching element such as flyback/freewheeling diode may inherently be less efficient due to greater losses from the diode conduction phase. However, the general principles of minimising switch transition losses whilst avoiding damage to the switch apply equally to DC-DC converters having a single power switch.

Also the embodiments described above have generally described current mode control converters operating in continuous conduction mode. As the skilled person will appreciated other modes of operation and control are known, such as discontinuous conduction mode and voltage mode control for example. In general however all such DC-DC converters involve power switch transitions and at least some of said transitions may result in induced voltage kicks on at least some of the internal nodes that increase the voltage stress on the switches or other components. The principles of the present invention, adjusting the rate of a switch transition based on operational conditions to mitigate the switch transition losses whilst remaining within the safe operating area for the switches, are applicable to any such DC-DC converter.

The discussion above has also referred to bond wire inductances and PCB inductance for the purposes of illustration only. The skilled person will appreciate that other packing technologies exist and some may not involve bond wires, for example chip scale packaging (CSP) technology. In general however there still be some inductance associated with the supply lines. Minimising the inductances associated with the supply lines will minimise the magnitude of any voltage kicks and allow the switch transitions to operate faster under all operating conditions of the converter.

It should also be noted that the discussion above has referred to the pre-drivers for the MOS switches driving from PVDD to PGND and vice versa. For many conventional MOS power switches the pre-drivers will have a rail-to-rail voltage output. However in some embodiments the voltage output may be limited. For example for some MOS switches, such as EDNMOS and other structures with thin gate oxide, there may be a lower maximum limit to the gate-source voltage than to the drain-source voltage, and hence the output of the pre-driver may be limited. Also, rather than a PMOS for the high-side switch, it may be advantageous to use an NMOS with a charge-pumped gate voltage to provide high enough gate voltage above its source when switched on. Many varieties of power switches, for instance JFET, MESFET, or bipolar transistors, may be used in embodiments of the present invention, with pre-drivers appropriate for the particular sort of power switch. Further the embodiments of the present invention may be combined with known techniques for improving efficiency. In particular the gate drive voltage of the power switches may be adjusted in accordance with known techniques for reducing gate charge losses as described above. Thus the output voltage of the pre-drivers may be adjusted in accordance with adjustment of the power switch strength.

In general the embodiments of the present invention therefore allow the rate of at least one transition of a power switch to be adjusted based on operational conditions, e.g. a supply voltage of the converter and/or inductor current and/or general signal indicating the operating conditions of a host device so that the switch may operate as fast as possible, to reduce power losses, but without exceeding safe operating voltage levels.

Such a DC-DC converter may be arranged as at least part of a power management circuit and may be implemented in a device, especially a portable and/or battery powered host device such as a mobile telephone, an audio player, a video player, a PDA, a mobile computing platform and/or a games device for example. In such applications the increased efficiency may give system-level benefits such as increased operating time before battery re-charge is needed.

Embodiments of the invention have been described in terms of DC-DC converters. In general however aspects of the present invention relate to the use of switch control circuitry to control the rate of turn-on and/or turn-off of a power switch, so as to reduce switch transition losses, where turn-on or turn-off of the switch may, in some conditions, lead to an increased voltage stress across the switch. In which case the operational conditions applying to the switch may be taken into account when controlling the turn-on and/or turn-off rate.

In another aspect, the invention also provide pre-driver circuitry for driving a power switch wherein the pre-driver circuitry has a variable drive strength that can be selected, and changed in use, so as to vary the rate of at least one of turn-on and turn-off of the switch.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

What is claimed is:

1. DC-DC converter circuitry comprising:
a first supply node for connection to a first voltage supply line;
a second supply node for connection to a second voltage supply line;
an inductor node for connection to an inductor;
a first power switch operably connected between said first supply node and said inductor node; and
switch control circuitry configured to controllably vary the rate of at least one of turn-on or turn-off of the first power switch.

2. DC-DC converter circuitry as claimed in claim 1 wherein said switch control circuitry is configured to vary said rate of at least one of turn-on or turn-off of the first power switch based on the operational conditions of the converter.

3. DC-DC converter circuitry as claimed in claim 1 wherein said switch control circuitry is configured to vary said rate of at least one of turn-on or turn-off of the first power switch based on at least one of the magnitude and the polarity of current flow out of the inductor node.

4. DC-DC converter circuitry as claimed in claim 1 wherein said switch control circuitry is configured to vary said rate of at least one of turn-on or turn-off of the first power switch based on at least one supply voltage of the converter.

5. DC-DC converter circuitry as claimed in claim 4 wherein said switch control circuitry is configured to vary said rate of at least one of turn-on or turn-off of the first power switch based on at least one of an input supply voltage; the output supply voltage or the voltage difference between supply voltages of the first and second voltage supply lines.

6. DC-DC converter circuitry as claimed in claim 1 wherein said switch control circuitry is configured to vary said rate of at least one of turn-on or turn-off of the first power switch based on an activity level and/or an operating mode of a host system.

7. DC-DC converter circuitry as claimed in claim 1 wherein said switch control circuitry comprises a control input for receiving a control signal for setting said rate of turn-on or turn-off of said first power switch.

8. DC-DC converter circuitry as claimed in claim 1 further comprising a switch element operably connected between said second supply node and said inductor node.

9. DC-DC converter circuitry as claimed in claim 8 wherein said switch element is a second power switch and wherein said switch control circuitry is configured to controllably vary the rate of at least one of turn-on and turn-off of said second power switch.

10. DC-DC converter circuitry as claimed in claim 1 operable as a buck converter wherein:
said first supply node is a high-side input supply node; and
said second supply node is a low-side input supply node;
wherein said switch control circuitry is configured to controllably vary the rate of turn-off of said first power switch.

11. DC-DC converter circuitry as claimed in claim 10 wherein said switch control circuitry is configured such that only the rate of turn-off of said first power switch is varied.

12. DC-DC converter circuitry as claimed in claim 1 operable as a boost converter wherein:
said first supply node is a low supply node; and
said second supply node is an output voltage supply node;
wherein said switch control circuitry is configured to controllably vary the rate of turn-off of said first power switch.

13. DC-DC converter circuitry as claimed in claim 1 operable as an buck-boost converter wherein:
said first supply node is a high-side supply voltage; and
said second supply node is an output supply node;
wherein said switch control circuitry is configured to controllably vary the rate of turn-off of said first power switch.

14. DC-DC converter circuitry as claimed in any of claim 1 operable as an inverting converter wherein:
said first supply node is a high-side input supply voltage; and
said second supply node is an output supply node;
wherein said switch control circuitry is configured to controllably vary the rate of turn-off of said first power switch.

15. DC-DC converter circuitry as claimed in claim 1 wherein said switch control circuitry comprises:
at least a first pre-driver having a variable drive strength; and
pre-driver control circuitry for controlling the drive strength of said first pre-driver.

16. DC-DC converter circuitry as claimed in claim 15 where said first pre-driver has a variable resistance and said pre-driver control circuitry controls said variable resistance.

17. DC-DC converter circuitry as claimed in claim 15 wherein said first-pre-driver has a variable maximum current output and said pre-driver control circuitry controls said maximum current output.

18. DC-DC converter circuitry as claimed in claim 15 wherein said first pre-driver comprises a plurality of parallel driver stages wherein the number of driver stages that contribute to the driver strength is selectable by said pre-driver control circuitry.

19. DC-DC converter circuitry as claimed in claim 18 wherein said plurality of driver stages have different driver strengths.

20. DC-DC converter circuitry as claimed in claim 1 wherein said switch control circuitry comprises at least one input for receiving at least one of a current signal indicative of current flow out of said inductor node and a voltage signal indicative of a supply voltage of the converter.

21. DC-DC converter circuitry as claimed in claim 20 wherein said switch control circuitry is configured to reduce said rate of at least one of turn-on and turn-off of said first power switch at relatively higher current flow out of said inductor node.

22. DC-DC converter circuitry as claimed in claim 20 wherein said switch control circuitry is configured to compare at least one of said current signal and said voltage signal with at least one threshold and control said rate of at least one of turn-on and turn-off of said first power based on said comparison.

23. DC-DC converter circuitry as claimed in claim 20 wherein said switch control circuitry comprises:
inputs for receiving both said current signal and said voltage signal; and
combining circuitry for producing a combined value wherein said rate of at least one of turn-on and turn-off of said first power switch is based on said combined value.

24. DC-DC converter circuitry as claimed in claim 23 wherein said combined value is substantially proportional to the value of the current signal and substantially inversely proportional to a constant minus the value of said voltage signal.

25. DC-DC converter circuitry as claimed in claim 1 wherein said switch control circuitry comprises:
an input for receiving an activity signal indicating the activity level of the host system or a signal indicating an operating mode of the host system.

26. DC-DC converter circuitry as claimed in claim 25 where said activity signal indicates the processing speed of a system processor.

27. DC-DC converter circuitry as claimed in claim 25 wherein said switch control circuitry is configured, in response to said activity signal indicating a change in operating conditions, to set the rate of turn-on and/or turn-off of said first power switch to a default level for a period of time.

28. DC-DC converter circuitry as claimed in claim 1 wherein said switch control circuitry is configured to set the rate of turn-on and/or turn-off of said first power switch to a default level in the absence of an indication of the operational conditions of the converter.

29. A power management circuit comprising a DC-DC converter as claimed in claim 1.

30. A device comprising a power management circuit as claimed in claim 29.

31. A device as claimed in claim 30 wherein the device is at least one of: a portable device; a battery powered device; a mobile telephone; an audio player, a video player; a personal data assistant; a mobile computing platform; a mobile games device; a video player.

32. A method of reducing power loss in a DC-DC converter having at least one power switch, the method comprising the steps of
varying the rate of at least one of turn-on and turn-off for at least one power switch.

33. DC-DC converter circuitry comprising:
at least one power switch;
pre-driver circuitry for driving said at least one power switch wherein
the pre-driver circuitry is configured such that the speed of at least one switch transition of said at least one power switch is controlled based on the operational conditions of the converter.

34. DC-DC converter circuitry comprising:
at least one power switch; and
switch control circuitry for driving said at least one power switch wherein:
the switch control circuitry is configured such that the rate of at least one of turn-on or turn-off of said at least one power switch is controlled based on a voltage induced across said switch during said turn-on or turn-off.

35. DC-DC converter circuitry comprising:
at least one power switch;
pre-driver circuitry configured to drive said at least one power switch;
wherein the pre-driver circuitry comprises a control input for altering the pre-driver drive strength.

36. Pre-driver circuitry for driving a power switch wherein the pre-driver circuitry has a drive strength that can be varied in use so as to vary the rate of at least one of turn-on and turn-off of the power switch.

37. DC-DC converter circuitry comprising:
a first node for connection to a supply voltage;
a second node for connection to a supply voltage;
a third node for connection to an inductor;
a power switch operably connected between said third node and one of said first node and said second node, said power switch having a control input; and
a switch controller having a drive output connected to said power switch control input;
wherein:
said switch controller has a control input terminal; and
the rate of turn-on or turn-off of the power switch is dependent on a control signal received at said switch controller control input terminal.
